(19) United States
(12) Patent Application Publication
(10) Pub. No.: US 2021/0313479 A1
(43) Pub. Date: Oct. 7, 2021

(54) High Power Density Solar Module and Methods of Fabrication

(71) Applicant: Bo Li, Sunnyvale, CA (US)

(72) Inventor: Bo Li, Sunnyvale, CA (US)

(21) Appl. No.: 16/927,356

(22) Filed: Jul. 13, 2020

Related U.S. Application Data
(60) Provisional application No. 63/005,379, filed on Apr. 5, 2020.
(60) Provisional application No. 63/041,886, filed on Jun. 20, 2020.

(51) Int. Cl. H01L 31/05; H01L 31/02

(52) U.S. Cl. CPC H01L 31/0504; H01L 31/0201

(57) ABSTRACT

A solar module that includes one or more strings of solar cells wherein at least one of the one or more strings includes a first pair of adjacent first and second solar cells; a second pair of adjacent first and second solar cells; wherein: the first pair is adjacent to the second pair; the first solar cell of each pair has a first polarity front surface and the second solar cell of each pair has an opposite polarity front surface; and the first solar cell of the second pair is adjacent to the second solar cell of the first pair.

This patent application claims priority under 35 U.S.C. 119(e) from a U.S. provisional patent application entitled “High Power Density Solar Module and Methods of Fabrication” having U.S. Provisional Appl. No. 63/005,379, which application was filed on Apr. 5, 2020, and from a U.S. provisional patent application entitled “High Power Density Solar Module and Methods of Fabrication” having U.S. Provisional Appl. No. 63/041,886, which application was filed on Jun. 20, 2020; all of which prior provisional patent applications are incorporated herein by reference in their entirety.

### TECHNICAL FIELD OF THE INVENTION

One or more embodiments relate to solar photovoltaic modules and methods of their fabrication.

### BACKGROUND OF THE INVENTION

A solar panel (also referred to as a solar module) is made typically by stringing together a plurality of photovoltaic solar cells (for example, full solar cells, half solar cells or cut solar cells), where photovoltaic solar cells are devices (comprised of p-n junctions formed in semiconductor material(s)) that convert photons into charge carriers. Charge carriers are collected at a front and back surface of the solar cell by metallization (for example, electrical contacts or terminals) coupled to surfaces of the semiconductor material(s). Then, the charge carriers produced by the solar cell are routed through interconnections with other solar cells in the solar module. FIG. 1 shows a top view of full solar cell 100 having three busbars, a top view of half solar cell 101 having three busbars, and a top view of cut solar cell 102. Standard monofacial crystalline solar cells generally have a front surface and a back surface where the front surface is designed to face the sun (and is typically covered by glass), and the back surface is typically covered by an opaque backsheet (typically an opaque polymer material for a monofacial solar cell). (For a typical bifacial solar cell, the back surface substrate can be a transparent polymer or glass)

In operation of a standard solar cell, charge carriers are collected from a front surface of the solar cell by “front metallization” (for example, an electrical contact or terminal) and from a back surface of the solar cell by “back metallization” (for example, an electrical contact or terminal). In particular, when the front metallization is adapted to collect such charge carriers, for example, negative charge carriers (i.e., electrons) or positive charge carriers (i.e., holes), the back metallization is adapted to collect charge carriers of opposite polarity from the charge carriers collected by the front metallization. In other words, if the front metallization is adapted to collect negative charge carriers, then the back metallization is adapted to collect positive carriers and vice versa. In this patent application, when a minus sign or a plus sign (indicating charge polarity) is associated with a surface of a solar cell, that means that negative or positive charge carriers, respectively, are collected from that surface when the solar cell is in operation. Further, in this patent application, the terms a negative or a positive metallization or electrical contact or terminal each means that the particular metallization or electrical contact or terminal is adapted to collect charge carriers of the designated polarity from a solar cell surface which provides such carriers when the solar cell is in operation. Thus, as a shorthand, for example, when a metallization or an electrical contact or a terminal is referred to as being negative (or minus), this means that the solar cell surface from which negative carriers are collected provides negative carriers when the solar cell is in operation and when a metallization or an electrical contact or a terminal is referred to as being positive (or plus), this means that the solar cell surface from which positive carriers are collected provides positive carriers when the solar cell is in operation. Similarly, in this patent application, the terms a negative or a positive solar cell surface or a negative or positive polarity surface means that the particular solar cell surface is adapted to provide charge carriers of the designated polarity when the solar cell is in operation. Thus, as a shorthand, for example, when a solar cell surface is referred to as being negative (or minus), this means that the solar cell surface provides negative charge carriers when the solar cell is in operation and when a solar cell surface is referred to as being positive (or plus), this means that the solar cell surface provides positive charge carriers when the solar cell is in operation.

Typical crystalline silicon solar cells have negative metallization coupled to their front surfaces or positive metallization coupled to their front surfaces. FIG. 2 shows an illustration of a partial cross-section of a semiconductor portion of: (a) p type front junction solar cell 110 with p-n junction 113 where minus sign 112 indicates that negative polarity carriers are to be collected from its front surface; (b) n type back junction solar cell 115 with p-n junction 118 where minus sign 117 indicates that negative polarity carriers are to be collected from its front surface; (c) n type front junction solar cell 120 with p-n junction 123 where plus sign 122 indicates that positive polarity carriers are to be collected from its front surface; and (d) p type back junction solar cell 125 with p-n junction 128 where plus sign 127 indicates that positive polarity carriers are to be collected from its front surface. Arrows 111, 116, 121, and 126 show the direction of sunlight impingement on the various solar cells. It is noted that a conventional monocrystalline p type solar cell, a Passivated Emitter and Rear solar cell (PERC solar cell), a conventional multicrystalline p type solar cell, and an n type heterojunction back junction solar cell typically have metallization (so called negative metallization) to collect negative polarity carriers from their front surface. In addition, an n type front junction solar cell, including an n type Passivated Emitter Rear Totally Diffused (PERT) monocrystalline silicon solar cell, and a p type back junction solar cell, have metallization (so-called positive metallization) to collect positive polarity carriers from their front surface. In addition, as is known, crystalline silicon solar cells typically have no busbars or have from one (1) busbar to seventeen (17) busbars. FIG. 3 shows a top view of full solar cell 130 having no busbars and top views of full solar cells 131-136 having 3 to 12 busbars, respectively.

FIG. 4 shows a top view of solar module 140 which is comprised of full solar cells having three (3) busbars. FIG. 4 illustrates how the full solar cells are electrically connected to provide solar module 140 in accordance with the prior art. Negative signs 141₁-141₁₂ depict the polarity of metallization coupled to the front surface (i.e., the polarity of charge carriers collected from the front surface) of each full solar cell in solar module 140. As indicated in FIG. 4, the polarity of the metallization coupled to the front surface of each full solar cell is negative (i.e., the metallization collects negative polarity carriers, i.e., electrons, from the front surface). FIG. 5 shows a top view of solar module 145 which is comprised of half solar cells having three (3) busbars. FIG. 5 illustrates how the half solar cells are electrically connected to provide solar module 145 in accordance with the prior art. Negative signs 146₁-146₂₄ depict the polarity of metallization coupled to the front surface of each half solar cell in solar module 145 (i.e., the polarity of charge carriers collected from the front surface). As indicated in FIG. 5, the polarity of the metallization coupled to the front surface of each half solar cell is negative (i.e., the metallization collects negative polarity carriers, i.e., electrons, from the front surface).

FIG. 6 shows a cross-section of a portion of solar module 150 comprised of solar cells 150₁-150₃ that are electrically connected in accordance with the prior art. Negative signs 152₁-152₃ indicate the polarity of metallization coupled to the front surface of solar cells 150₁-150₃ (i.e., the polarity of charge carriers collected from the front surface) in solar module 150 and arrows 151 show the direction of sunlight impingement on solar cells 150₁-150₃. The space between adjacent solar cells 150₁ and 150₂ is indicated by 155 and the space between solar cells 150₂ and 150₃ is indicated by 158. In FIG. 6: (a) busbars 153 and 154 are affixed to fingers on the front and back surfaces of solar cell 150₁, respectively; (b) busbars 156 and 157 are affixed to fingers on the front and back surfaces of solar cell 150₂, respectively; and (c) busbars 159 and 160 are affixed to fingers on the front and back surfaces of solar cell 150₃, respectively. In accordance with the prior art, and as shown in FIG. 6, busbar 154 is electrically connected to busbar 156 by ribbon 161₁ and busbar 157 is electrically connected to busbar 159 by ribbon 161₂ (typically, during fabrication, ribbon 161₁ completely covers busbar 154 and busbar 156 and ribbon 161₂ completely covers busbar 157 and busbar 159). To provide this arrangement, for example, a conductive ribbon is: (a) soldered to a busbar on the back surface of one cell; and (b) soldered onto a busbar on the front surface of the next cell, thereby forming a series electrical contact. This series connection causes the voltage of the separate solar cells to add, while the current passing through all of the cells is the same. In this configuration, the space between adjacent cells is typically 2 mm to enable the conductive ribbon to pass through the space while leaving enough room for stress release during cycles between high temperature and low temperature.

FIG. 6 also shows a cross-section of a portion of solar module 170 comprised of solar cells 170₁-170₃ that are electrically connected in accordance with the prior art. Positive signs 171₁-171₃ indicate the polarity of metallization coupled to the top surface of solar cells 170₁-170₃ in solar module 170 (i.e., the polarity of charge carriers collected from the front surface). As shown in FIG. 6, the configuration for electrically connecting the solar cells of solar module 170 is the same as that shown for solar module 150.

The methodology for electrically connecting solar cells in solar modules 150 and 170 shown in FIG. 6 is problematic for several reasons. A first reason is that the 2 mm space between solar cells is a non-photoactive area within the solar module, and as result, power density is reduced. A second reason is that, due to extending ribbons through intercell gaps, the ribbon-busbar solder area close to an edge of a cell is prone to accumulation of stress. This potentially leads to microcracks and hot spots in the field.

Various configurations have been proposed and implemented in the prior art to reduce the non-photoactive area between solar cells in a solar module. One such configuration is referred to as a “shingle” module. To fabricate such a “shingle module, as shown in FIG. 7, a full, busbarless solar cell is cut into smaller solar cells 178₁-178ₙ (for example, a full cell may be cut into 3 to 8 pieces). Then, as shown in FIG. 7, the cut solar cells are connected using conductive adhesive to form shingle module 176. As shown in FIG. 7, arrows 177 show the direction of sunlight impingement on the various solar cells. Since a front edge of one cut cell is glued to a back edge of an adjacent cut cell, there is no gap between cut cells in the shingle module. As a result, power density is improved. However, since cut cell edges are overlapped, more cells are needed to provide a shingle module and, as a result, cost is increased. In addition, since one cut cell is stacked on top of an adjacent cut cell at an edge, the long term field reliability of such a configuration needs to be verified.

Another method to reduce cell-to-cell gap in solar modules in the prior art is to use a narrow gap. FIG. 8A shows a cross-section of a portion of solar module 179 comprised of solar cells 180₁-180₃ in accordance with the prior art. Cell-to-cell gap 181₁ between solar cells 180₁ and 180₂ and cell-to-cell gap 181₂ between solar cells 180₂ and 180₃ have been reduced. For example, attempts have been made to reduce these cell-to-cell gaps from 2 mm to 0.5 mm One result of this is that the power density of solar module 179 increases. However, since the cell-to-cell gap is much smaller, a thinner ribbon (for example, a 0.1 mm ribbon) is used to be able to accommodate it within the smaller gap. The thinner ribbon replaces a thicker ribbon having a thickness between 0.15 mm to 0.25 mm. However, this is problematic because the thinner ribbon increases resistivity, and thereby, reduces the power of solar module 179 by about 4 watts.

Lastly, FIG. 8B shows an alternative configuration of “overlapping” solar module 185 in accordance with the prior art. In this alternative configuration, there is a cell edge-to-cell edge overlap between adjacent cells 187₁-187₄. However, instead of using conductive adhesive to connect the cells as described above, Z-shaped thin ribbons (for example, ribbons 189₁-189₃) are used. Although this improves power density, module reliability becomes challenging —especially for temperature cycles.

### SUMMARY OF THE INVENTION

One or more embodiments address one or more of the problems described above. In particular, one or more embodiments address a power density issue due to the above-described large cell-to-cell gap in solar modules fabricated in accordance with the prior art. In addition, one or more embodiments address a reliability issue due to the above-described stress accumulation around ribbons in intercell gaps in solar modules fabricated in accordance with the prior art.

One or more embodiments are solar modules that include one or more strings of solar cells wherein at least one of the one or more strings includes a first pair of adjacent first and second solar cells; a second pair of adjacent first and second solar cells; wherein: the first pair is adjacent to the second pair; the first solar cell of each pair has a first polarity front surface and the second solar cell of each pair has an opposite polarity front surface; and the first solar cell of the second pair is adjacent to the second solar cell of the first pair.

### BRIEF DESCRIPTION OF THE DRAWINGS

FIG. 1 shows a top view of full solar cell 100 having three busbars, a top view of half solar cell 101 having three busbars, and a top view of cut solar cell 102.

FIG. 2 shows an illustration of a partial cross-section of a semiconductor portion of: (a) p type front junction solar cell 110 with p-n junction 113 where minus sign 112 indicates that negative polarity carriers are to be collected from its front surface; (b) n type back junction solar cell 115 with p-n junction 118 where minus sign 117 indicates that negative polarity carriers are to be collected from its front surface; (c) n type front junction solar cell 120 with p-n junction 123 where plus sign 122 indicates that positive polarity carriers are to be collected from its front surface; and (d) p type back junction solar cell 125 with p-n junction 128 where plus sign 128 indicates that positive polarity carriers are to be collected from its front surface.

FIG. 3 shows a top view of full solar cell 130 having no busbars and top views of full solar cells 131-136 having 3 to 12 busbars, respectively.

FIG. 4 shows a top view of solar module 140 which is comprised of full solar cells having three (3) busbars.

FIG. 5 shows a top view of solar module 145 which is comprised of half solar cells having three (3) busbars.

FIG. 6 shows: (a) a cross-section of a portion of solar module 150 comprised of solar cells 150₁-150₃ that are electrically connected in accordance with the prior art; and (b) a cross-section of a portion of solar module 170 comprised of solar cells 170₁-170₃ that are electrically connected in accordance with the prior art.

FIG. 7 shows how a solar module comprised of “shingles” is constructed.

FIG. 8A shows a cross-section of a portion of solar module 179 comprised of solar cells 180₁-180₃ in accordance with the prior art.

FIG. 8B shows an alternative configuration of “overlapping” solar module 185 in accordance with the prior art.

FIG. 9 shows a cross-section of a portion of solar module 200 that is fabricated in accordance with one or more embodiments (where the electrical contacts are not shown in the cross-section to facilitate understanding).

FIG. 10 shows a top view of solar module 220 (fabricated in accordance with one or more embodiments) comprised of full solar cells having electrical contacts (that include busbars) coupled to their front and back surfaces.

FIG. 11 shows: (a) a top view of a portion of the top side of solar module 220 shown in FIG. 10; (b) a cross-section of the portion of solar module 220 shown in FIG. 10 (where the electrical contacts are not shown in the cross-section to facilitate understanding); and (c) a bottom view of the portion of the back side of solar module 220 shown in FIG. 10, respectively—where the solar cells are connected in series.

FIG. 12A shows a top view of solar module 230 (fabricated in accordance with one or more embodiments) comprised of 144 half solar cells having electrical contacts (that include busbars) coupled to their front and back surfaces in a symmetrical module design having bypass diodes 231₁-231₃ in the middle thereof.

FIG. 12B shows a top view of solar module 235 (fabricated in accordance with one or more embodiments) comprised of 150 half solar cells having electrical contacts (that include busbars) coupled to their front and back surfaces in a module design having bypass diodes 236₁-236₃ on the side.

FIG. 13 shows: (a) a top view of a portion of the top side of solar module 230 shown in FIG. 12A (also applies to solar module 235 shown in FIG. 12B); (b) a cross-section of the portion of solar module 230 shown in FIG. 12A (also applies to solar module 235 shown in FIG. 12B) (where the electrical contacts are not shown in the cross-section to facilitate understanding); and (c) a bottom view of the portion of the back side of solar module 230 shown in FIG. 12A (also applies to solar module 235 shown in FIG. 12B), respectively—where the solar cells are connected in series.

FIG. 14 shows a top view of solar module 240 (fabricated in accordance with one or more embodiments) comprised of cut solar cells having electrical contacts (that includes busbars) coupled to their front and back surfaces.

FIG. 15 shows: (a) a top view of a portion of the top side of solar module 240 shown in FIG. 14; (b) a cross-section of the portion of solar module 240 shown in FIG. 14 (where the electrical contacts are not shown in the cross-section to facilitate understanding); and (c) a bottom view of the portion of the back side of solar module 240 shown in FIG. 14, respectively—where the solar cells are connected in series.

FIG. 16 shows a top view of solar module 250 (fabricated in accordance with one or more embodiments) comprised of full solar cells having electrical contacts coupled to their front and back surfaces which are interconnected by wires coupled to the electric contacts.

FIG. 17 shows: (a) a top view of a portion of the top side of solar module 250 shown in FIG. 16; (b) a cross-section of the portion of solar module 250 shown in FIG. 16 (where the electrical contacts are not shown in the cross-section to facilitate understanding); and (c) a bottom view of the portion of the back side of solar module 250 shown in FIG. 16, respectively—where the solar cells are connected in series.

FIG. 18 shows a top view of solar module 260 (fabricated in accordance with one or more embodiments) comprised of half solar cells having electrical contacts coupled to their front and back surfaces which are interconnected by wires coupled to the electric contacts in a symmetrical module design having bypass diodes 257₁-257₃ in the middle thereof.

FIG. 19 shows: (a) a top view of a portion of the top side of solar module 260 shown in FIG. 18; (b) a cross-section of the portion of solar module 260 shown in FIG. 18 (where the electrical contacts are not shown in the cross-section to facilitate understanding); and (c) a bottom view of the portion of the back side of solar module 260 shown in FIG. 18, respectively—where the solar cells are connected in series.

FIG. 20 shows a top view of solar module 270 (fabricated in accordance with one or more embodiments) comprised of cut solar cells having electrical contacts coupled to their front and back surfaces which are interconnected by wires coupled to the electric contacts.

FIG. 21 shows: (a) a top view of a portion of the top side of solar module 270 shown in FIG. 20; (b) a cross-section of the portion of solar module 270 shown in FIG. 20 (where the electrical contacts are not shown in the cross-section to facilitate understanding); and (c) a bottom view of the portion of the back side of solar module 270 shown in FIG. 20, respectively—where the solar cells are connected in series.

FIG. 22 shows a top view of solar module 280 (fabricated in accordance with one or more embodiments) comprised of full solar cells having electrical contacts comprised of mesh metallization structures with electrical connection pads coupled to the front and back surfaces.

FIG. 23 shows: (a) a top view of a portion of the top side of solar module 280 shown in FIG. 22; (b) a cross-section of the portion of solar module 280 shown in FIG. 22 (where the electrical contacts are not shown in the cross-section to facilitate understanding); and (c) a bottom view of the portion of the back side of solar module 280 shown in FIG. 22, respectively—where the solar cells are connected in series.

FIG. 24 shows a top view of solar module 290 (fabricated in accordance with one or more embodiments) comprised of half solar cells having electrical contacts comprised of mesh metallization structures with electrical connection pads coupled to the front and back surfaces.

FIG. 25 shows: (a) a top view of a portion of the top side of solar module 290 shown in FIG. 24; (b) a cross-section of the portion of solar module 290 shown in FIG. 24 (where the electrical contacts are not shown in the cross-section to facilitate understanding); and (c) a bottom view of the portion of the back side of solar module 290 shown in FIG. 24, respectively—where the solar cells are connected in series.

FIG. 26 shows a top view of solar module 300 (fabricated in accordance with one or more embodiments) comprised of cut solar cells having electrical contacts comprised of mesh metallization structures with electrical connection pads coupled to the front and back surfaces.

FIG. 27 shows: (a) a top view of a portion of the top side of solar module 300 shown in FIG. 26; (b) a cross-section of the portion of solar module 300 shown in FIG. 26 (where the electrical contacts are not shown in the cross-section to facilitate understanding); and (c) a bottom view of the portion of the back side of solar module 300 shown in FIG. 24, respectively—where the solar cells are connected in series.

FIG. 28 shows a top view of solar module 400 (fabricated in accordance with one or more embodiments) comprised of half solar cells having electrical contacts (that include busbars) coupled to their front and back surfaces) in a symmetrical module design having bypass diodes in the middle thereof.

FIG. 29 shows: (a) a top view of a portion of the top side of solar module 400 shown in FIG. 28; (b) a cross-section of the portion of solar module 400 shown in FIG. 28 (where the electrical contacts are not shown in the cross-section to facilitate understanding); and (c) a bottom view of the portion of the back side of solar module 400 shown in FIG. 28, respectively—where the solar cells are connected in series.

FIG. 30 shows a top view of solar module 410 (fabricated in accordance with one or more embodiments) comprised of half solar cells wherein wires provide electrical interconnection in a symmetrical module design having bypass diodes in the middle thereof.

FIG. 31 shows: (a) a top view of a portion of the top side of solar module 410 shown in FIG. 30; (b) a cross-section of the portion of solar module 410 shown in FIG. 30 (where the electrical contacts are not shown in the cross-section to facilitate understanding); and (c) a bottom view of the portion of the back side of solar module 410 shown in FIG. 30, respectively—where the solar cells are connected in series.

FIG. 32 shows a top view of solar module 420 (fabricated in accordance with one or more further embodiments) comprised of half solar cells having electrical contacts comprised of metal metallization structures with electrical connection pads coupled to the front and back surfaces) in a symmetrical module design having bypass diodes in the middle thereof.

FIG. 33 shows: (a) a top view of a portion of the top side of solar module 420 shown in FIG. 32; (b) a cross-section of the portion of solar module 420 shown in FIG. 32 (where the electrical contacts are not shown in the cross-section to facilitate understanding); and (c) a bottom view of the portion of the back side of solar module 420 shown in FIG. 32, respectively—where the solar cells are connected in series.

FIG. 34 shows a plan view of a surface (front or back surface) of solar cell 500 that has an electrical contact comprised of a rectangular, mesh metallization structure with electrical connection pads (disposed at or near an edge) coupled thereto in accordance with one or more embodiments.

FIG. 35 shows a plan view of a surface (front or back surface) of solar cell 510 that has an electrical contact comprised of a pseudo-circular web, mesh metallization structure with electrical connection pads (disposed at or near an edge) coupled thereto in accordance with one or more embodiments.

FIG. 36 shows a free-standing metallic article that can be coupled to a front and/or back surface of a solar cell.

FIGS. 37A and 37B show electrical contacts in the form of metallizations for use in conjunction with a free-standing metallic article.

FIG. 38 shows: (a) a top view of a portion of the top side of a solar module that is fabricated in accordance with one or more embodiments; (b) a cross-section of the portion of the solar module (where the electrical contacts are not shown in the cross-section to facilitate understanding); and (c) a bottom view of the portion of the back side of the solar module, respectively.

FIG. 39 shows: (a) a top view of a portion of the top side of a solar module that is fabricated in accordance with one or more further embodiments; (b) a cross-section of the portion of the solar module (where the electrical contacts are not shown in the cross-section to facilitate understanding); and (c) a bottom view of the portion of the back side of the solar module, respectively.

FIG. 40 shows cell-to-cell, surface electrical contact, interconnectors 600 and 610 for use in fabricating one or more embodiments.

FIG. 41 shows a cross-section of a portion of solar module 700 that is fabricated in accordance with one or more embodiments (where the electrical contacts are not shown in the cross-section to facilitate understanding).

FIG. 42 shows: (a) a top view of a portion of the top side of solar module 800 that is fabricated in accordance with one or more embodiments; (b) a cross-section of the portion of solar module 800 (where the electrical contacts are not shown in the cross-section to facilitate understanding); and (c) a bottom view of the portion of the back side of solar module 800, respectively.

FIG. 43A shows a plan view of a surface (front or back surface) of solar cell 900 that has an electrical contact comprised of a rectangular, padless, mesh metallization structure coupled thereto in accordance with one or more embodiments.

FIG. 43B shows interconnector wire mesh 950 that is fabricated in accordance with one or more embodiments.

FIG. 43C shows a top view of the front surfaces of two solar cells like solar cell 900 that are interconnected by wire mesh 950 in accordance with one or more embodiments and a cross-section of the interconnected solar cells (where the electrical contacts are not shown in the cross-section to facilitate understanding).

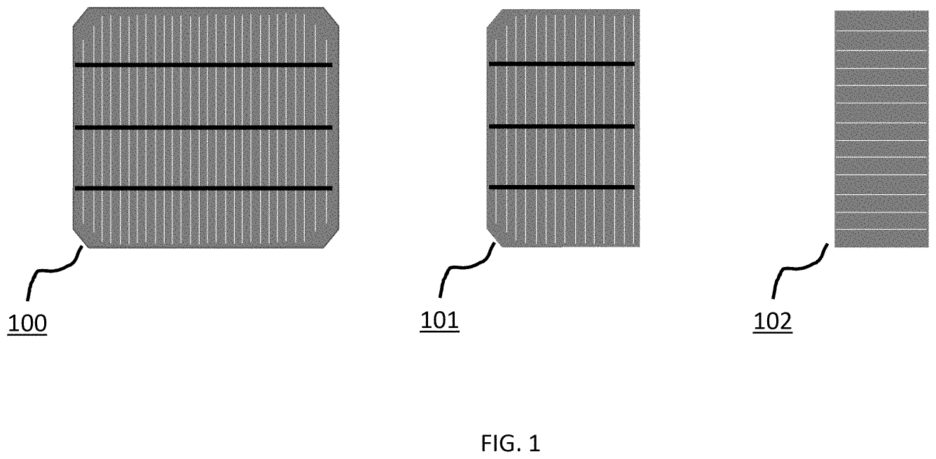

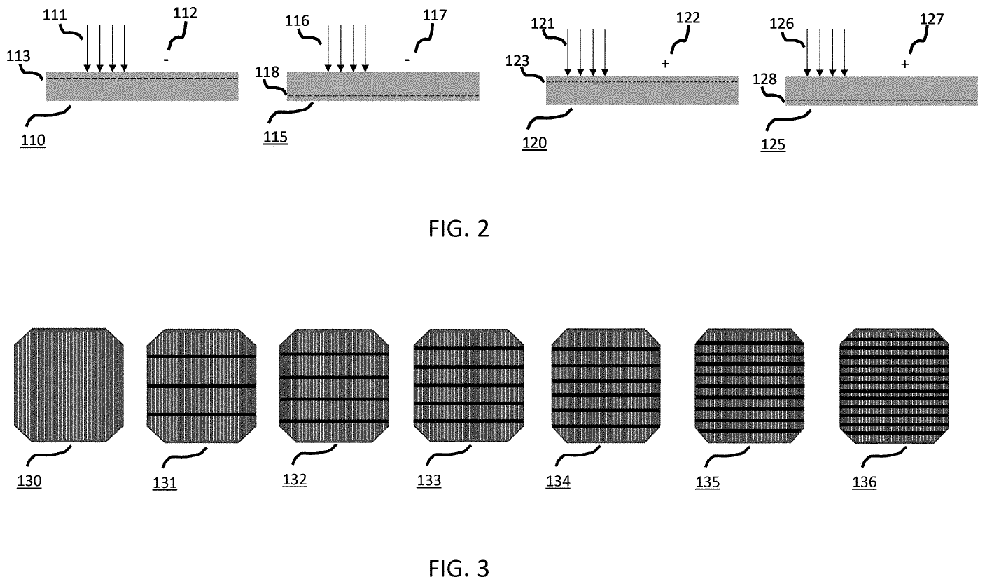

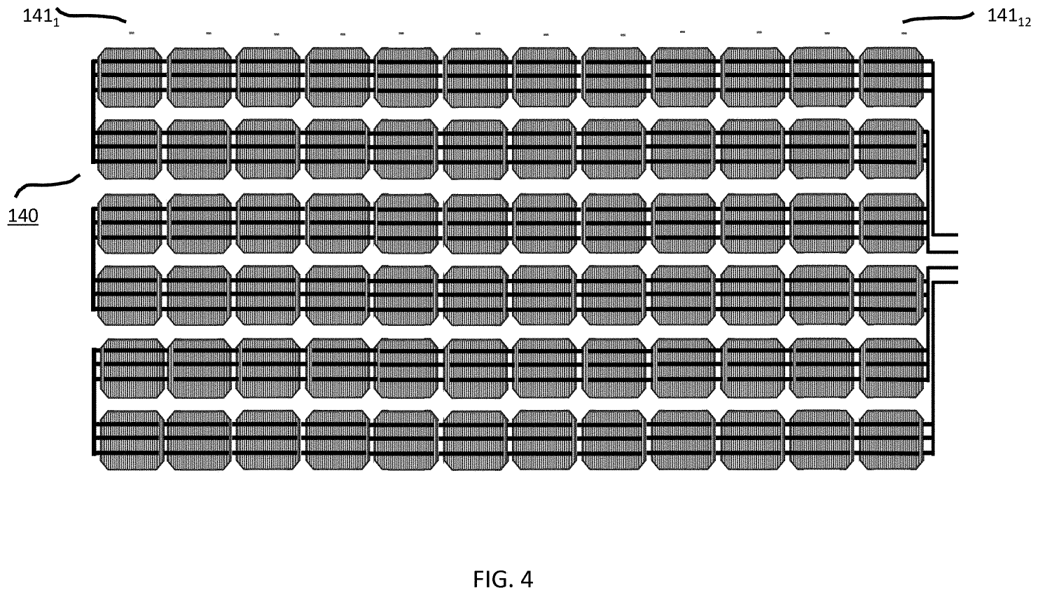

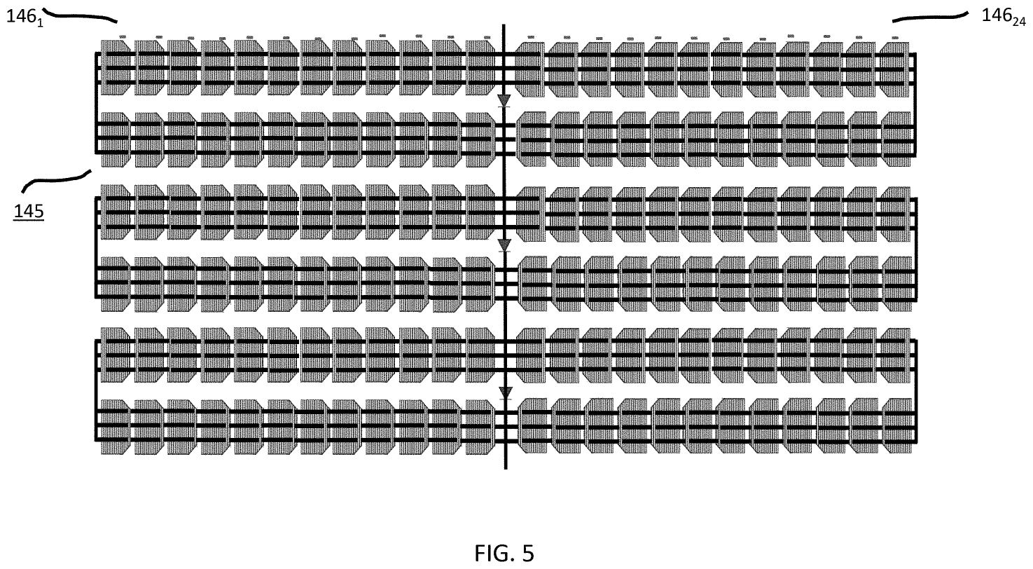

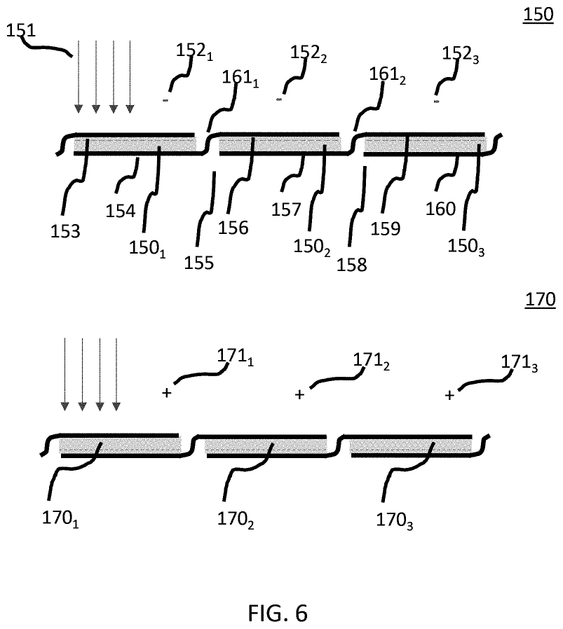

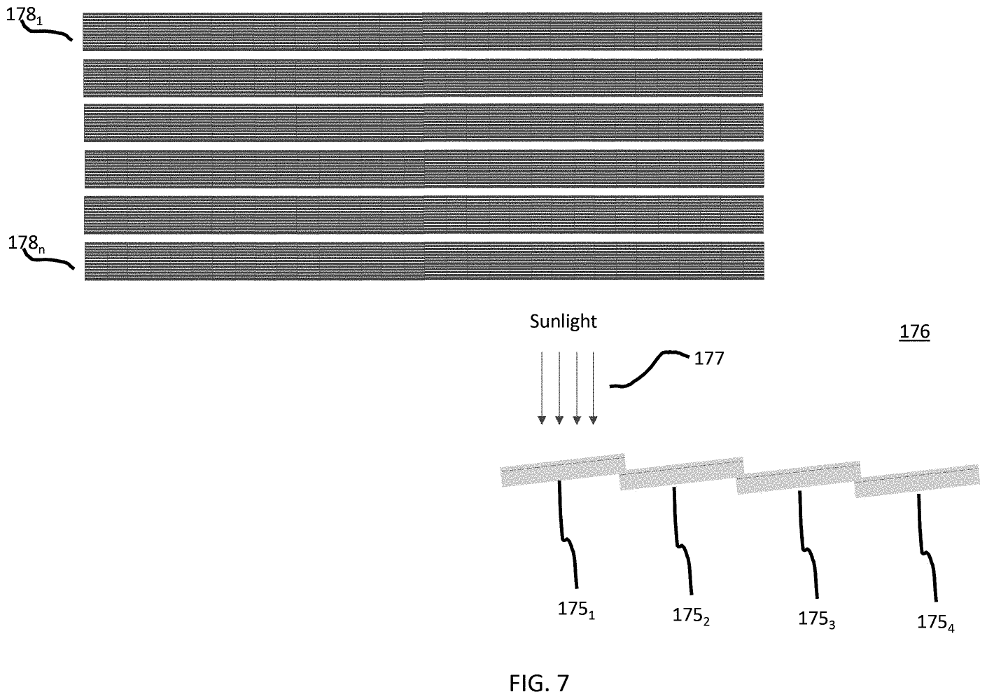

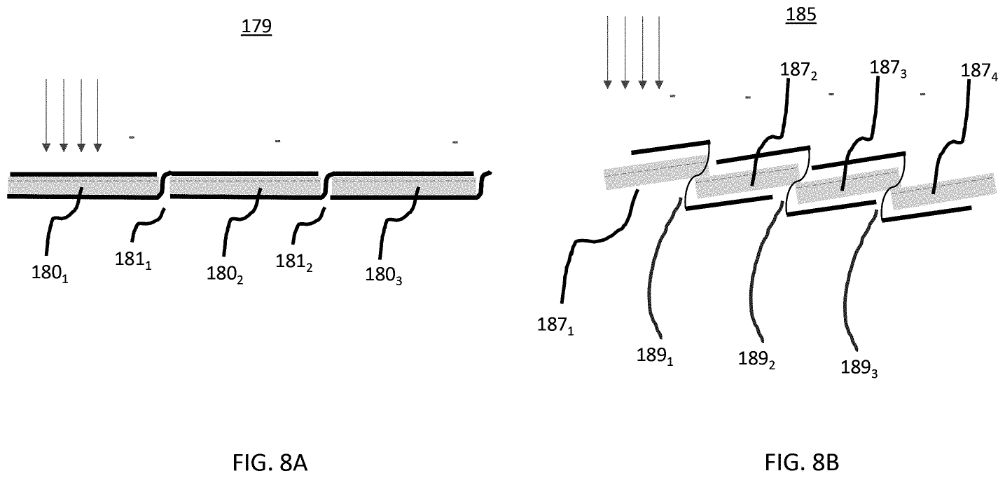

### DETAILED DESCRIPTION

As set forth above, but repeated here for clarity in this patent application, a solar panel (also referred to as a solar module) is made typically by stringing together a plurality of photovoltaic solar cells (for example and without limitation, full solar cells, half solar cells or cut solar cells), where photovoltaic solar cells are devices (comprised of p-n junctions formed in semiconductor material(s)) that convert photons into charge carriers. Charge carriers are collected at a front and back surface of a solar cell by metallization (for example, electrical contacts or terminals) coupled to surfaces of the semiconductor material(s). Then, the charge carriers produced by the solar cell are routed through interconnections with other solar cells in the solar module. As used in this patent application, the term surface of a solar cell means the semiconductor surface from which charge carriers are collected when the solar cell is in operation, the term front refers to the surface upon which sunlight is intended to impinge and the term back refers to the surface opposite to the front.

In operation of a solar cell, charge carriers are collected from a front surface of the solar cell by “front metallization” (for example, an electrical contact or terminal) coupled to the front surface and from a back surface of the solar cell by “back metallization” (for example, an electrical contact or terminal) coupled to the back surface. In particular, when the front metallization is adapted to collect such charge carriers, for example, negative charge carriers (i.e., electrons) or positive charge carriers (i.e., holes), the back metallization is adapted to collect charge carriers of opposite polarity from the charge carriers collected by the front metallization. In other words, if the front metallization is adapted to collect negative charge carriers, then the back metallization is adapted to collect positive carriers and vice versa. In this patent application, when a minus sign or a plus sign (indicating charge polarity) is associated with a surface of a solar cell, that means that negative or positive charge carriers, respectively, are collected from the surface when the solar cell is in operation. Further, in this patent application, the terms a negative or a positive metallization or electrical contact or terminal each means that the particular metallization or electrical contact or terminal is adapted to collect charge carriers of the designated polarity from a solar cell surface which provides such carriers when the solar cell is in operation. As a shorthand, whenever a metallization or an electrical contact or a terminal is referred to as being negative (or minus), this means that the solar cell surface from which negative carriers are collected provides negative carriers when the solar cell is in operation and when a metallization or an electrical contact or a terminal is referred to as being positive (or plus), this means that the solar cell surface from which positive carriers are collected provides positive carriers when the solar cell is in operation. Similarly, in this patent application, also, as a shorthand, whenever a solar cell surface is referred to as being negative (or minus) or as being a negative polarity surface, this means that the solar cell surface provides negative charge carriers when the solar cell is in operation and when a solar cell surface is referred to as being positive (or plus) or as being a positive polarity surface, this means that the solar cell surface provides positive charge carriers when the solar cell is in operation.

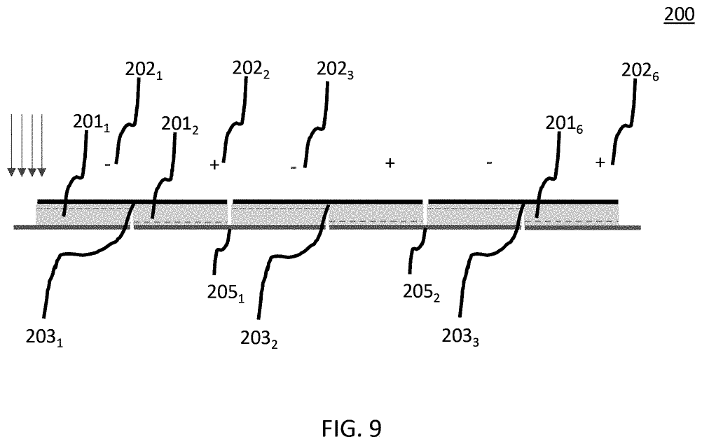

FIG. 9 shows a cross-section of a portion of solar module 200 that is fabricated in accordance with one or more embodiments (where the electrical contacts are not shown in the cross-section to facilitate understanding). As shown in FIG. 9, the portion of solar module 200 comprises solar cells 201₁-201₆ comprised of metallization coupled to their front and back surfaces, which metallizations are comprised of busbars (i.e., the metallizations are electrical contacts that include busbars). As shown in FIG. 9: (a) minus sign 202₁ indicates that solar cell 201₁ has a negative metallization (i.e., a negative electrical contact) coupled to its front surface (i.e., a negative front surface that provides negative charge carriers when solar cell 201₁ is in operation); (b) plus sign 202₂ indicates that solar cell 201₂ (adjacent to solar cell 201₁) has a positive metallization (i.e., a positive electrical contact) coupled to its front surface (i.e., a positive front surface that provides positive charge carriers when the solar cell 201₂ is in operation); (c) minus sign 202₃ indicates that solar cell 201₃ (adjacent to solar cell 201₂) has a negative metallization (i.e., a negative electrical contact) coupled to its front surface (i.e., a negative front surface that provides negative charge carriers when solar cell 201₃ is in operation); and (d) so forth. Thus, in accordance with one or more such embodiments, solar module 200 comprises solar cells having alternating negative and positive metallization (i.e., negative and positive electrical contacts) coupled to the front surfaces of adjacent cells and, therefore, corresponding alternating positive and negative metallization (i.e., positive and negative electrical contacts) coupled to the back surfaces of adjacent cells—where the solar cells are connected in series. In other words, in accordance with one or more such embodiments, solar module 200 comprises solar cells having alternating negative and positive front surfaces of adjacent cells and, therefore, corresponding alternating positive and negative back surfaces of adjacent cells—where the solar cells are connected in series.

As further shown in FIG. 9, in accordance with one or more embodiments: (a) metallizations (including busbars) (i.e., front electrical contacts) coupled to the front surface of solar cells 201₁ and 201₂ are electrically connected by front electrical connectors 203₁ (in FIG. 9, front electrical connectors 203₁ (for example, ribbons, that cover and couple to the busbars) couple to the front contacts of solar cells 201₁ and 201₂); (b) metallizations (including busbars) (i.e., front electrical contacts) coupled to the front surface of solar cells 201₃ and 201₄ are electrically connected by front electrical connectors 203₂ (in FIG. 9, front electrical connectors 203₂ (for example, ribbons, that cover and couple to the busbars) couple to the front contacts of solar cells 201₃ and 201₄); (c) metallizations (including busbars) (i.e., front electrical contacts) coupled to the front surface of solar cells 201₅ and 201₆ are electrically connected by front electrical connectors 203₃ (in FIG. 9, front electrical connectors 203₃ (for example, ribbons, that cover and couple to the busbars) couple to the front contacts of solar cells 201₅ and 201₆); (d) metallizations (including busbars) (i.e., back electrical contacts) coupled to the back surface of solar cells 201₂ and 201₃ are electrically connected by back electrical connectors 205₁ (in FIG. 9, back electrical connectors 205₁ (for example, ribbons, that cover and couple to the busbars) couple to the back contacts of solar cells 201₂ and 201₃); and (e) metallizations (including busbars) (i.e., back electrical contacts) coupled to the back surface of solar cells 201₄ and 201₅ are electrically connected by back electrical connectors 205₂ (in FIG. 9, back electrical connectors 205₂ (for example, ribbons, that cover and couple to the busbars) couple to the back contacts of solar cells 201₄ and 201₅).

In accordance with one or more embodiments, the front and back electrical connectors may be ribbons (for example and without limitation, straight ribbons that do not extend through cell-to-cell gaps, or straight ribbons that do not extend into cell-to-cell gaps) that are soldered to the busbars comprising the front and back electrical contacts of the solar cells in the pattern described above in conjunction with FIG. 9 where, for example and without limitation, the ribbons extend completely over the busbars on the cells. For example, and without limitation, such front and back electrical connectors may be tin coated, copper ribbons such as those manufactured by Wuxi Sveck Technology Co., Ltd. of No. 16, Sun'an Rd., Wuxi, Jiangsu China. For example, and without limitation, such ribbons may comprise 99.97% copper which is coated with a 60% Sn/40% Pb alloy, or a 62% Sn/36% Pb/2% Ag alloy, or a 97% Sn/3% Ag alloy. As a result of fabricating solar module 200 in accordance with one or more such embodiments, advantageously, there is no need for a ribbon (or other electrical connector) to be extended through the gap between cells as is the case for the prior art. Since there is no such through-extension of electrical connectors (for example, straight ribbons), reliability of the one or more embodiments may be enhanced since stress may be evenly distributed for example, along a ribbon. In addition, reliability may be enhanced because stress at soldering points between ribbons and busbars at the edges of wafers may also be reduced as compared to the prior art where ribbons need to be extended through gaps between cells. In accordance with one or more embodiments, gaps between two adjacent cell edges can be in a range from about 5 mm to about 0.001 mm. In further addition, in accordance with one or more further embodiments, gaps between two adjacent cell edges can be reduced from 2 mm to less than 0.5 mm (for example, the gaps can be reduced to small dimensions such as, for example, 0.001 mm), thereby improving power density.

Various embodiments are described below in conjunction with the remaining figures. As used herein, the term a “string” refers to a series-connected set of solar cells.

I. Full Solar Cells Having Electrical Contacts (that Include Busbars) Coupled to their Front and Back Surfaces

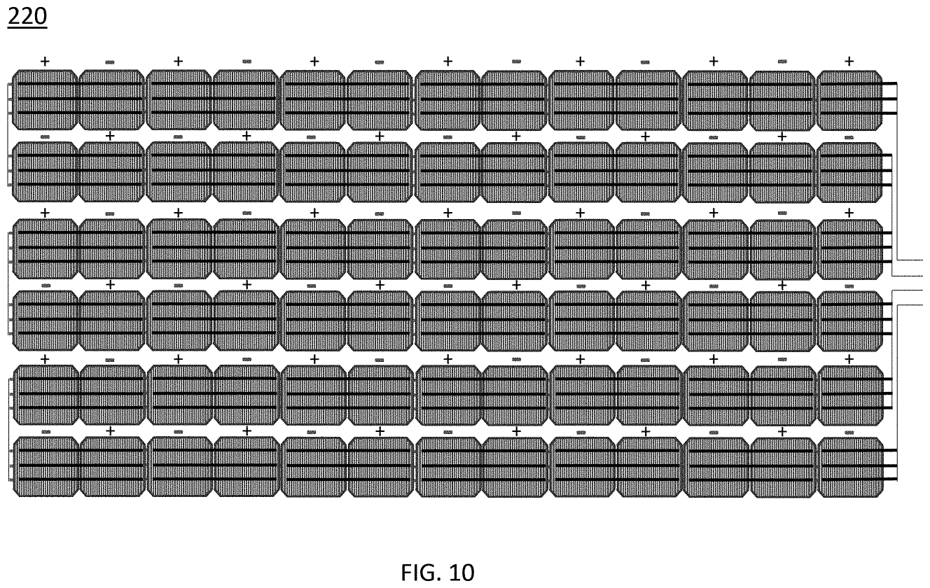

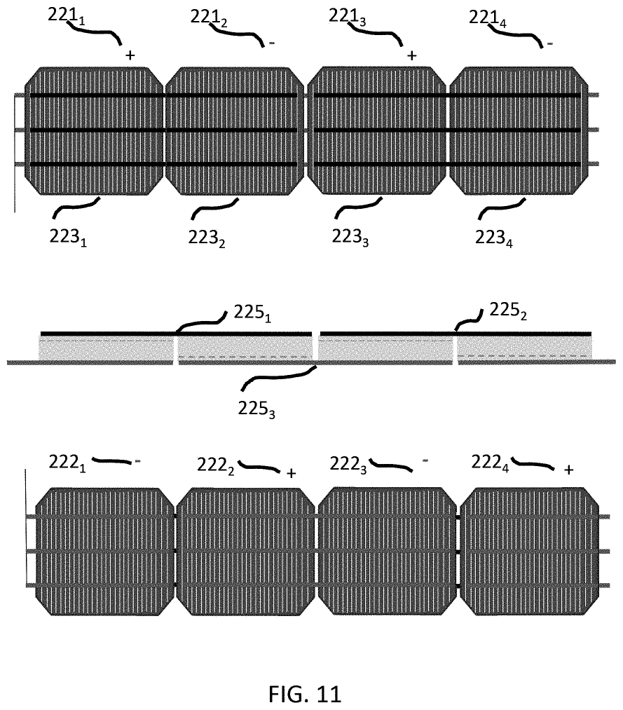

In accordance with one or more embodiments, a solar module is fabricated using full solar cells comprised of metallization which includes busbars (i.e., electrical contacts that include busbars) coupled to their front and back surfaces (full solar cells include, for example and without limitation, full square solar cells and pseudo square full cells). The number of busbars on a full solar cell can range, for example and without limitation, from one (1) to seventeen (17) or more. FIG. 10 shows a top view of solar module 220 (fabricated in accordance with one or more embodiments) comprised of full solar cells having electrical contacts (that include busbars) coupled to their front and back surfaces. FIG. 10 shows how the full solar cells are electrically connected, and the plus and minus signs show the electrical polarity of the electrical contacts coupled to the front surfaces of the solar cells and the electrical polarity of charge carriers provided by the front surfaces of the solar cells when the solar cells are in operation. As can be seen from FIG. 10, in accordance with one or more embodiments, solar module 220 comprises six (6) strings of full solar cells having alternating negative and positive metallization (i.e., electrical contacts) coupled to the front surfaces of adjacent cells and, therefore, corresponding alternating positive and negative metallization (i.e., electrical contacts) coupled to the back surfaces of adjacent cells—where the solar cells are connected in series. In other words, in accordance with one or more such embodiments, solar module 220 comprises six (6) strings of full solar cells having alternating negative and positive front surfaces of adjacent cells and, therefore, corresponding alternating positive and negative back surfaces of adjacent cells—where the solar cells are connected in series. FIG. 11 shows: (a) a top view of a portion of the top side of solar module 220 shown in FIG. 10; (b) a cross-section of the portion of solar module 220 shown in FIG. 10 (where the electrical contacts are not shown in the cross-section to facilitate understanding); and (c) a bottom view of the portion of the back side of solar module 220 shown in FIG. 10, respectively—where the solar cells are connected in series.

In FIG. 11, in accordance with one or more such embodiments, plus signs 221₁ and 221₃ and minus signs 221₂ and 221₄ show the electrical polarity of metallization (i.e., front electrical contacts) coupled to the front surfaces of full solar cells 223₁-223₄ (i.e., a negative metallization (negative front electrical contact) collects negative charge carriers from a negative front surface, which negative front surface provides negative charge carriers when the particular solar cell is in operation and a positive metallization (positive front electrical contact) collects positive charge carriers from a positive front surface, which positive front surface provides positive charge carriers when the particular solar cell is in operation). In addition, in accordance with one or more such embodiments, plus signs 222₂ and 222₄ and minus signs 222₁ and 222₃ show the electrical polarity of metallization (i.e., back electrical contacts) coupled to the back surfaces of full solar cells 223₁-223₄ (i.e., a negative metallization (negative back electrical contact) collects negative charge carriers from a negative back surface, which negative back surface provides negative charge carriers when the particular solar cell is in operation and a positive metallization (positive back electrical contact) collects positive charge carriers from a positive back surface, which positive back surface provides positive charge carriers when the particular solar cell is in operation). In addition, in accordance with one or more such embodiments: (a) front electrical connectors 225₁ provide electrical connection between metallization (front electrical contacts) coupled to the front surfaces of full solar cells 223₁ and 223₂ (in FIG. 11, front electrical connectors 225₁ (for example, ribbons, that cover and couple to the busbars) couple to the front contacts of full solar cells 223₁ and 223₂); (b) front electrical connectors 225₂ provide electrical connection between metallization (front electrical contacts) coupled to the front surfaces of solar cells 223₃ and 223₄ (in FIG. 11, front electrical connectors 225₂ (for example, ribbons, that cover and couple to the busbars) couple to the front contacts of full solar cells 223₃ and 223₄); and (c) back electrical connectors 225₃ provide electrical connection between metallization (back electrical contacts) coupled to the back surfaces of full solar cells 223₂ and 223₃ (in FIG. 11, back electrical connectors 225₃ (for example, ribbons, that cover and couple to the busbars) couple to the back contacts of full solar cells 223₂ and 223₃). In accordance with one or more such embodiments, the electrical connectors (i.e., the cell-to-cell, electrical connectors of metallizations (electrical contacts) which are connected in the above-described configuration) may be, for example and without limitation, ribbons, such as straight ribbons that do not extend through cell-to-cell gaps, or straight ribbons that do not extend into cell-to-cell gaps where, for example and without limitation, the ribbons extend completely over the busbars on the surfaces of the cells. Examples of suitable such ribbons are, without limitation, tin coated, copper ribbons such as those manufactured by Wuxi Sveck Technology Co., Ltd. of No. 16, Sun'an Rd., Wuxi, Jiangsu China. In further particular, suitable ribbons may comprise 99.97% copper which is coated with a 60% Sn/40% Pb alloy, or a 62% Sn/36% Pb/2% Ag alloy, or a 97% Sn/3% Ag. The ribbons may be affixed to the metallizations (electrical contacts) by affixing them to the busbars by soldering, by use of conductive bonding, or by use of other known electrical bonding methods. In addition, the electrical connectors may be fabricated by affixing any one of a number of conducting tapes that are well known, such as conductive adhesive tape to the busbars.

In accordance with one or more embodiments, gaps between two adjacent solar cell edges (i.e., gaps shown in FIGS. 10 and 11) can be in a range from about 5 mm to about 0.001 mm. In further addition, in accordance with one or more further embodiments, gaps between two adjacent cell edges can be reduced from 2 mm to less than 0.5 mm (for example, the gaps can be reduced to small dimensions such as, for example, 0.001 mm).

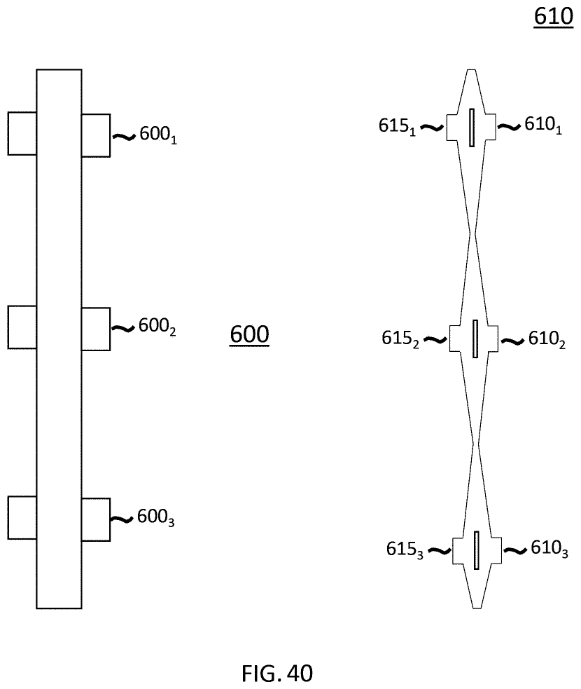

FIG. 40 shows cell-to-cell, surface electrical contacts, interconnectors 600 and 610 for use in fabricating one or more embodiments (interconnector 610 is shown in U.S. Pat. No. 7,390,961). Interconnectors 600 and 610 are comprised of an electrically conductive material, for example, copper, which may be used in fabricating one or more embodiments of solar modules, for example and without limitation, embodiments where solar cells have metallization coupled to a front and/back surface (electrical contacts) that is comprised of: (a) busbars or (b) a mesh metallization structure with electrical conduction pads. In use, interconnector tabs of interconnector 600 or interconnector 610 are connected: (a) to the busbars of adjacent solar cells or (b) to the electrical conduction pads (for example and without limitation, soldering pads) of adjacent solar cells. Alternatively, the interconnector tabs may be affixed to the electrical conduction pads or the busbars using conductive bonding.

As shown in FIG. 40, interconnector 600 comprises a single, continuous, electrically conductive material with interconnector tabs (for connection to electrical contact pads coupled to a solar cell by, for example and without limitation, soldering or conductive bonding or for connection to busbars coupled to a solar cell by, for example and without limitation, soldering or conductive bonding). As further shown in FIG. 40, interconnector 610 comprises a single, continuous, electrically conductive material having several regions. Each region of interconnector 610 may have: (a) a diamond-shaped body; (b) interconnector tabs (for connection to electrical contact pads on a solar cell by, for example and without limitation, soldering or conductive bonding or for connection to busbars on a solar cell by, for example and without limitation, soldering or conductive bonding); and (c) an in-plane slit (for example and without limitation, in-plane slits 615₁-615₃) or other strain-relief features. Slits 615₁-615₃ may provide strain relief.

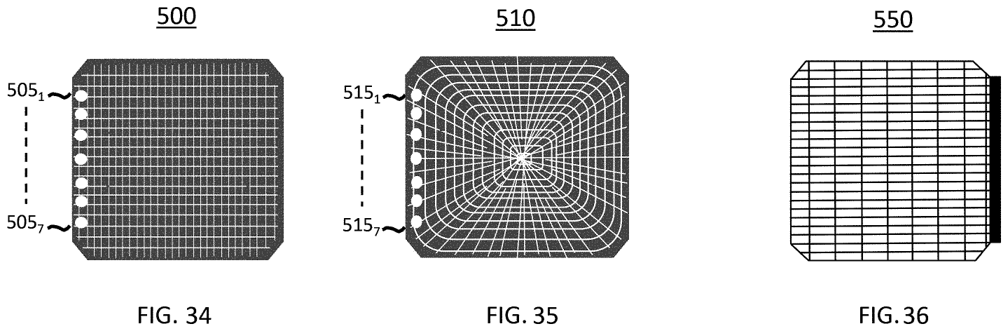

The electrically conductive material of interconnectors 600 and 610 can have multiple interconnector tabs on each side (for example and without limitation, such as interconnector tabs 600₁-600₃ on interconnector 600 and interconnector tabs 610₁-610₃ on interconnector 610). The interconnector tabs may be connected to pads comprising an electrical contact coupled to a solar cell surface such as pads shown in FIGS. 34 and 35. As indicated by FIG. 40, interconnectors 600 and 610 are best provided as a single-piece design to make them more robust and durable.

In accordance with one or more embodiments, a solar module like solar module 220 can be fabricated, for example and without limitation, using full solar cells of alternating p type PERC full solar cells (providing a front negative electrical contact on its front surface, which front surface is a negative front surface that provides negative charge carriers when the solar cell is in operation) and n type Tunnel Oxide Passivated Contact (Topcon) full solar cells (providing a front positive electrical contact on its front surface, which front surface is a positive front surface that provides positive charge carriers when the solar cell is in operation). In accordance with one or more further embodiments, a solar module like solar module 220 can be fabricated, for example and without limitation, using full solar cells of alternating p type PERC full solar cells (providing a negative electrical contact on its front surface, which front surface is a negative front surface that provides negative charge carriers when the solar cell is in operation) and p type back junction full solar cells (providing a positive electrical contact on its front surface, which front surface is a positive front surface that provides positive charge carriers when the solar cell is in operation). In accordance with one or more further embodiments, a solar module like solar module 220 can be fabricated, for example and without limitation, using full solar cells of alternating n type Topcon full solar cells (providing a positive electrical contact on its front surface, which front surface is a positive front surface that provides positive charge carriers when the solar cell is in operation) and n type back junction full solar cells (providing a negative electrical contact on its front surface, which front surface is a negative front surface that provides negative charge carriers when the solar cell is in operation). In accordance with one or more further embodiments, a solar module like solar module 220 can be fabricated, for example and without limitation, using solar cells of alternating n type front junction heteroj unction full solar cells (providing a positive electrical contact on its front surface, which front surface is a positive front surface that provides positive charge carriers when the solar cell is in operation) and n type back junction full solar cells (providing a negative electrical contact on its front surface, which front surface is a negative front surface that provides negative charge carriers when the solar cell is in operation).

II. Half Solar Cells Having Electrical Contacts (that Include Busbars) Coupled to their Front and Back Surfaces

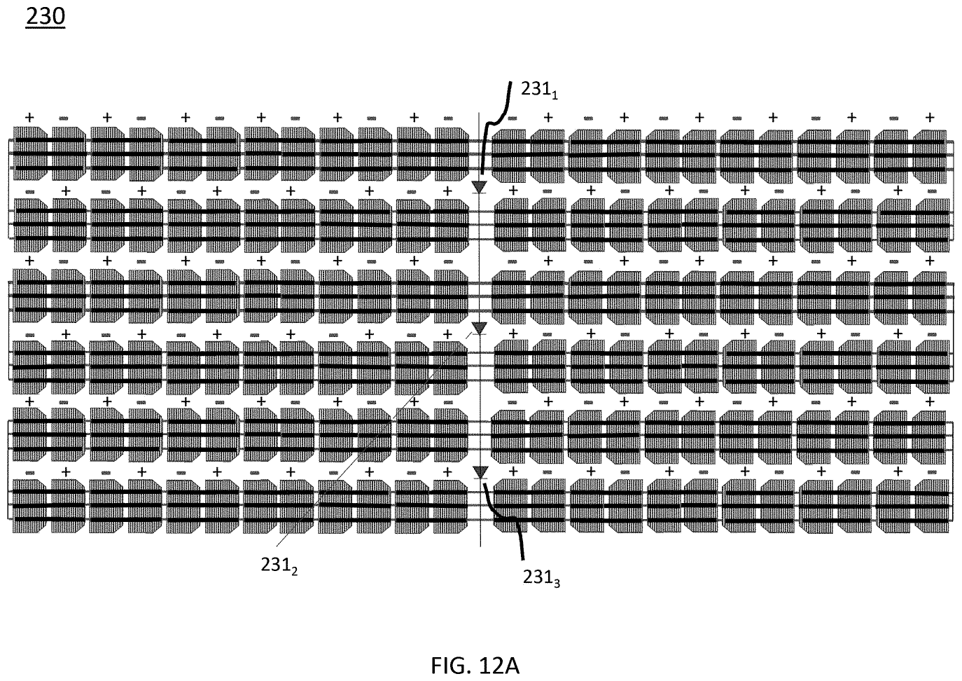

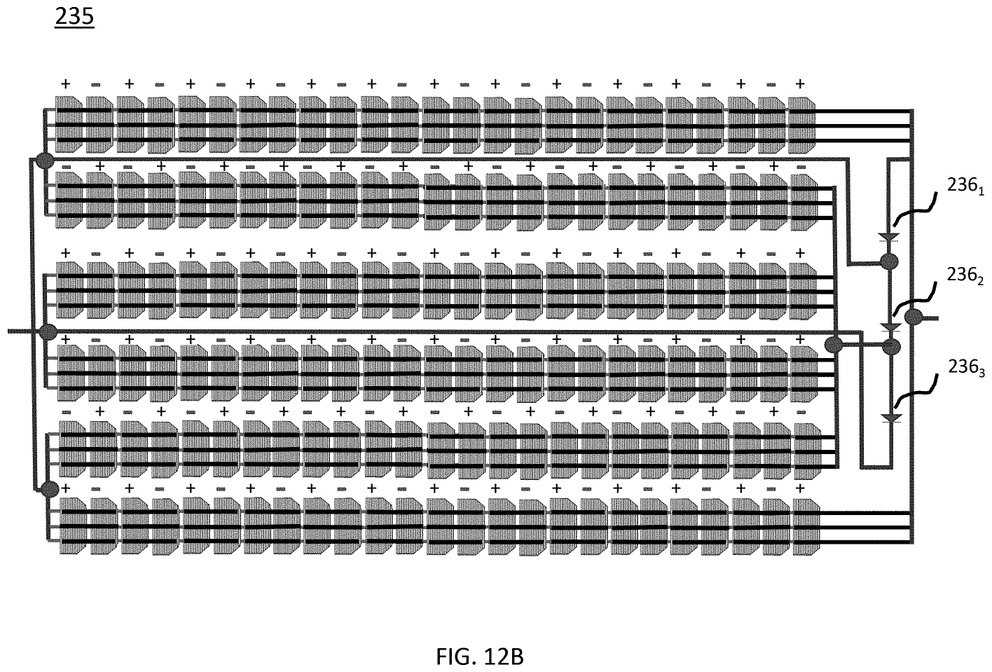

In accordance with one or more embodiments, a solar module is fabricated using half solar cells comprised of metallization which includes busbars (i.e., electrical contacts that include busbars) coupled to their front and back surfaces. The number of busbars on a half solar cell can range, for example and without limitation, from one (1) to seventeen (17) or more. FIG. 12A shows a top view of solar module 230 (fabricated in accordance with one or more embodiments) comprised of 144 half solar cells having electrical contacts (that include busbars) coupled to their front and back surfaces in a symmetrical module design having bypass diodes 231₁-231₃ in the middle thereof. FIG. 12B shows a top view of solar module 235 (fabricated in accordance with one or more embodiments) comprised of 150 half solar cells having electrical contacts (that include busbars) coupled to their front and back surfaces in a module design having bypass diodes 236₁-236₃ on the side.

FIGS. 12A and 12B show how the half solar cells are electrically connected, and the plus and minus signs show the electrical polarity of the electrical contacts coupled to the front surfaces of the half solar cells and the electrical polarity of charge carriers provided by the front surfaces of the half solar cells when the half solar cells are in operation. As can be seen from FIGS. 12A and 12B, in accordance with one or more embodiments, solar module 230 comprises twelve (12) strings and solar module 235 comprises six (6) strings of half solar cells having alternating negative and positive metallization (i.e., electrical contacts) coupled to the front surfaces of adjacent half cells and, therefore, corresponding alternating positive and negative metallization (i.e., electrical contacts) coupled to the back surfaces of adjacent half cells—where the solar cells are connected in series. In other words, in accordance with one or more such embodiments, solar module 230 comprises twelve (12) strings and solar module 235 comprises six (6) strings of half solar cells having alternating negative and positive front surfaces of adjacent cells and, therefore, corresponding alternating positive and negative back surfaces of adjacent cells—where the solar cells are connected in series.

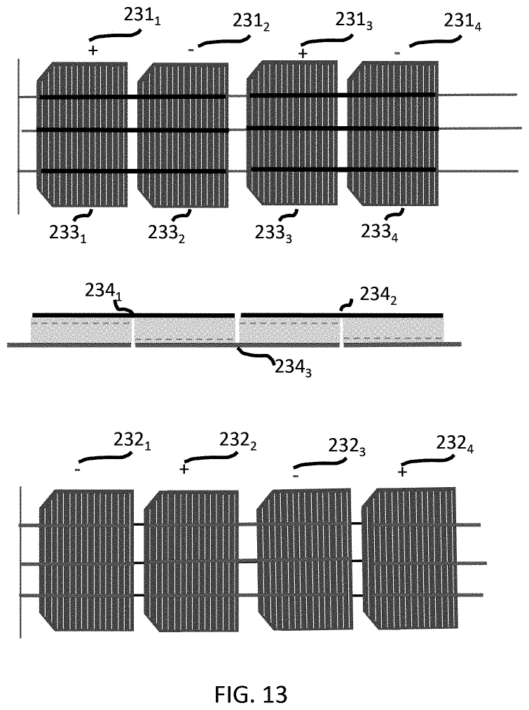

FIG. 13 shows: (a) a top view of a portion of the top side of solar module 230 shown in FIG. 12A (also applies to solar module 235 shown in FIG. 12B); (b) a cross-section of the portion of solar module 220 shown in FIG. 12A (also applies to solar module 235 shown in FIG. 12B) (where the electrical contacts are not shown in the cross-section to facilitate understanding); and (c) a bottom view of the portion of the back side of solar module 230 shown in FIG. 12A (also applies to solar module 235 shown in FIG. 12B), respectively—where the solar cells are connected in series.

In FIG. 13, in accordance with one or more such embodiments, plus signs 231₁ and 231₃ and minus signs 231₂ and 231₄ show the electrical polarity of metallization (i.e., front electrical contacts) coupled to the front surfaces of half solar cells 233₁-233₄ (i.e., a negative metallization (negative front electrical contact) collects negative charge carriers from a negative front surface, which negative front surface provides negative charge carriers when the particular solar cell is in operation and a positive metallization (positive front electrical contact) collects positive charge carriers from a positive front surface, which positive front surface provides positive charge carriers when the particular solar cell is in operation). In addition, in accordance with one or more such embodiments, plus signs 232₂ and 232₄ and minus signs 232₁ and 232₃ show the electrical polarity of metallization (i.e., back electrical contacts) coupled to the back surfaces of half solar cells 233₁-233₄ (i.e., a negative metallization (negative back electrical contact) collects negative charge carriers from a negative back surface, which negative back surface provides negative charge carriers when the particular solar cell is in operation and a positive metallization (positive back electrical contact) collects positive charge carriers from a positive back surface, which positive back surface provides positive charge carriers when the particular solar cell is in operation). In addition, in accordance with one or more such embodiments: (a) front electrical connectors 234₁ provide electrical connection between metallization (front electrical contacts) coupled to the front surfaces of half solar cells 233₁ and 233₂ (in FIG. 13, front electrical connectors 234₁ (for example, ribbons, that cover and couple to the busbars) couple to the front contacts of half solar cells 233₁ and 233₂); (b) front electrical connectors 234₂ provide electrical connection between metallization (front electrical contacts) coupled to the front surfaces of half solar cells 233₃ and 233₄ (in FIG. 13, front electrical connectors 234₂ (for example, ribbons, that cover and couple to the busbars) couple to the front contacts of half solar cells 233₃ and 233₄); and (c) back electrical connectors 234₃ provide electrical connection between metallization (back electrical contacts) coupled to the back surfaces of half solar cells 233₂ and 233₃ (in FIG. 13, back electrical connectors 234₃ (for example, ribbons, that cover and couple to the busbars) couple to the back contacts of half solar cells 233₂ and 233₃).

In accordance with one or more such embodiments, the electrical connectors (i.e., the cell-to-cell, electrical connectors of metallizations (electrical contacts) which are connected in the above-described configuration) may be, for example and without limitation, ribbons, such as straight ribbons that do not extend through cell-to-cell gaps, or straight ribbons that do not extend into cell-to-cell gaps where, for example and without limitation, the ribbons extend completely over the busbars on the cells. Examples of suitable such ribbons were described above regarding embodiments in conjunction with “Full solar cells having electrical contacts (that include busbars) coupled to their front and back surfaces” and FIG. 11. The ribbons may be affixed to the metallizations (electrical contacts) by affixing them to the busbars by soldering, by use of conductive bonding, or by use of other known electrical bonding methods. In addition, the electrical connectors may be fabricated by affixing any one of a number of conducting tapes that are well known, such as conductive adhesive tape to the busbars. In further addition, the electrical connectors may be interconnectors 600 or 610 described above in conjunction with FIG. 40.

In accordance with one or more embodiments, gaps between two adjacent solar cell edges (i.e., gaps shown in FIGS. 12A, 12B and 13) can be in a range from about 5 mm to about 0.001 mm. In further addition, in accordance with one or more further embodiments, gaps between two adjacent cell edges can be reduced from 2 mm to less than 0.5 mm (for example, the gaps can be reduced to small dimensions such as, for example, 0.001 mm).

In accordance with one or more embodiments, solar modules like solar modules 230 and 235 can be fabricated, for example and without limitation, using halves of the types of full solar cells described above regarding embodiments in conjunction with “Full solar cells having electrical contacts (that include busbars) coupled to their front and back surfaces” and FIG. 11 (i.e., regarding p and n type solar cells).

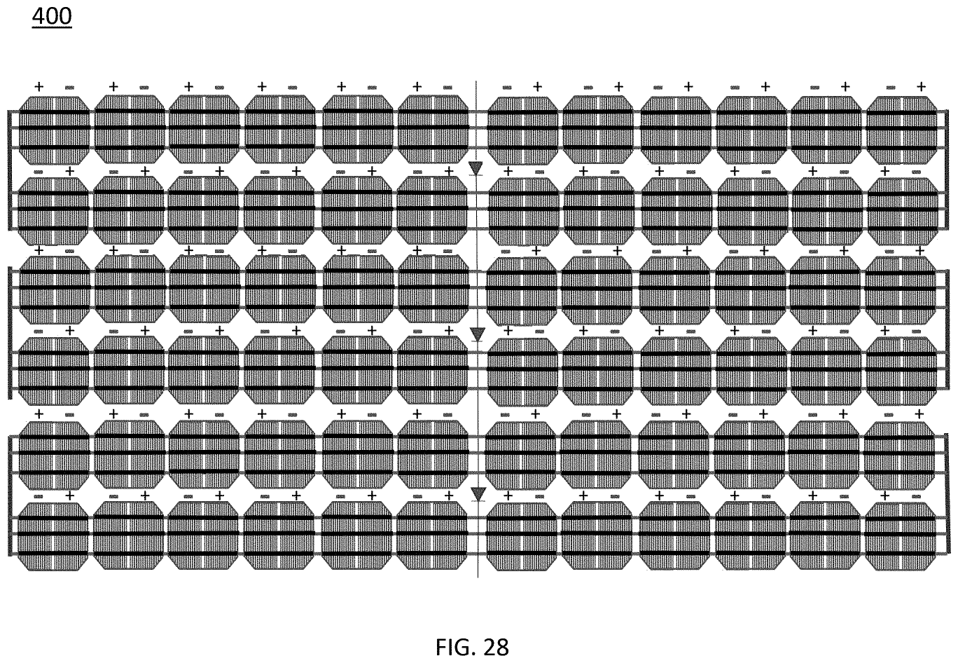

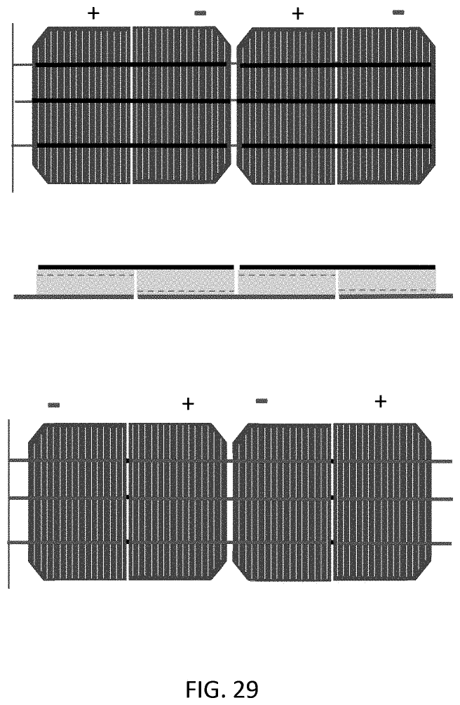

FIG. 28 shows a top view of solar module 400 (fabricated in accordance with one or more embodiments) comprised of twelve (12) strings of half solar cells having electrical contacts (that include busbars) coupled to their front and back surfaces) in a symmetrical module design having bypass diodes in the middle thereof. FIG. 29 shows: (a) a top view of a portion of the top side of solar module 400 shown in FIG. 28; (b) a cross-section of the portion of solar module 400 shown in FIG. 28 (where the electrical contacts are not shown in the cross-section to facilitate understanding); and (c) a bottom view of the portion of the back side of solar module 400 shown in FIG. 28, respectively—where the solar cells are connected in series.

Solar module 400 and the manner in which the half cells comprising solar module 400 are connected is the same as for solar module 230 shown in FIG. 12A except for the relative orientation of alternating half solar cells to each other (as seen, for example, by comparing FIGS. 13 and 29).

III. Cut Solar Cells Having Electrical Contacts (that Include Busbars) Coupled to their Front and Back Surfaces

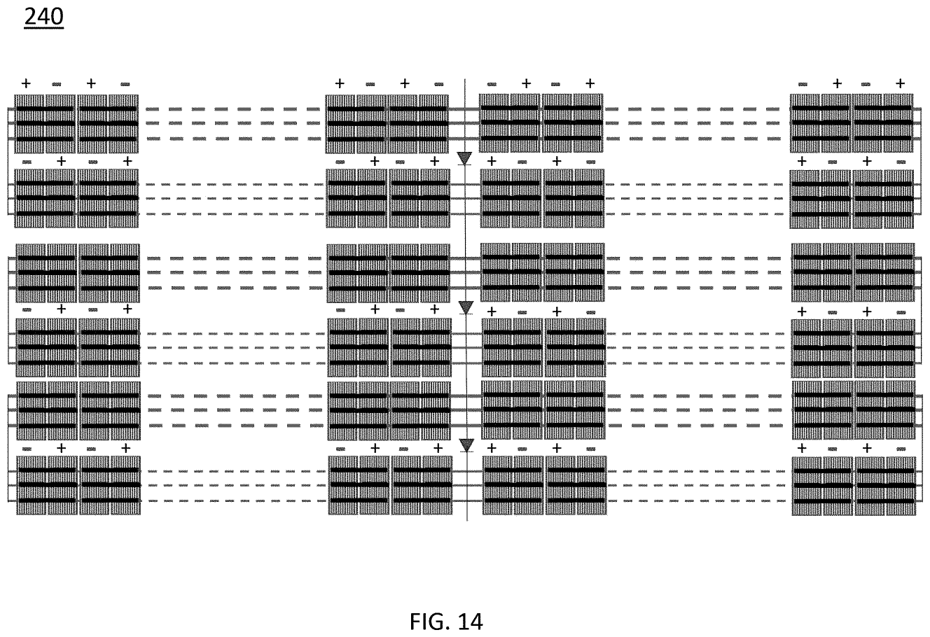

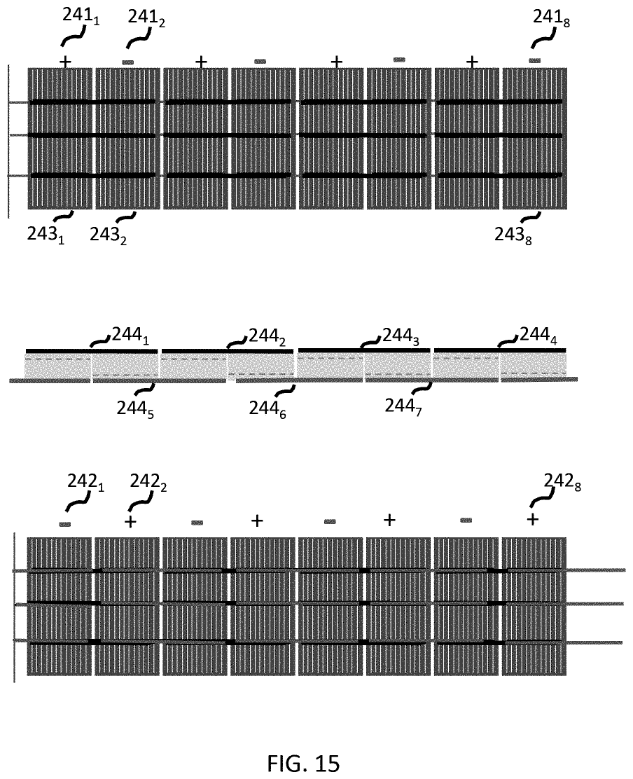

In accordance with one or more embodiments, a solar module is fabricated using cut solar cells comprised of metallization which includes busbars (i.e., electrical contacts that include busbars) coupled to their front and back surfaces. The number of busbars on a cut solar cell can range, for example and without limitation, from one (1) to seventeen (17) or more. FIG. 14 shows a top view of solar module 240 (fabricated in accordance with one or more embodiments) comprised of cut solar cells having electrical contacts that (that includes busbars) coupled to their front and back surfaces. FIG. 14 shows how the cut solar cells are electrically connected, and the plus and minus signs show the electrical polarity of the electrical contacts coupled to the front surfaces of the cut solar cells and the electrical polarity of charge carriers provided by the front surfaces of the cut solar cells when the cut solar cells are in operation. As can be seen from FIG. 14, in accordance with one or more embodiments, solar module 240 comprises twelve (12) strings of cut solar cells having alternating negative and positive metallization (i.e., electrical contacts) coupled to the front surfaces of adjacent cells and, therefore, corresponding alternating positive and negative metallization (i.e., electrical contacts) coupled to the back surfaces of adjacent cells—where the solar cells are connected in series. In other words, in accordance with one or more such embodiments, solar module 240 comprises twelve (12) strings of cut solar cells having alternating negative and positive front surfaces of adjacent cells and, therefore, corresponding alternating positive and negative back surfaces of adjacent cells—where the solar cells are connected in series. FIG. 15 shows: (a) a top view of a portion of the top side of solar module 240 shown in FIG. 14; (b) a cross-section of the portion of solar module 240 shown in FIG. 14 (where the electrical contacts are not shown in the cross-section to facilitate understanding); and (c) a bottom view of the portion of the back side of solar module 240 shown in FIG. 14, respectively—where the solar cells are connected in series.

In FIG. 15, in accordance with one or more such embodiments, plus signs 241₁, 241₃, 241₅ and 241₇ and minus signs 241₂, 241₄, 241₆, and 241₈ show the electrical polarity of metallization (i.e., front electrical contacts) coupled to the front surfaces of solar cells 243₁-243₈ (i.e., a negative metallization (negative front electrical contact) collects negative charge carriers from a negative front surface, which negative front surface provides negative charge carriers when the particular solar cell is in operation and a positive metallization (positive front electrical contact) collects positive charge carriers from a positive front surface, which positive front surface provides positive charge carriers when the particular solar cell is in operation). In addition, in accordance with one or more such embodiments, plus signs 242₂, 242₄, 242₆, and 242₈ and minus signs 242₁, 242₃, 242₅ and 242₇ show the electrical polarity of metallization (i.e., back electrical contacts) coupled to the back surfaces of solar cells 243₁-243₈ (i.e., a negative metallization (negative back electrical contact) collects negative charge carriers from a negative back surface, which negative back surface provides negative charge carriers when the particular solar cell is in operation and a positive metallization (positive back electrical contact) collects positive charge carriers from a positive back surface, which positive back surface provides positive charge carriers when the particular solar cell is in operation). In addition, in accordance with one or more such embodiments: (a) front electrical connectors 244₁ provide electrical connection between metallization (front electrical contacts) coupled to the front surfaces of cut solar cells 243₁ and 243₂ (in FIG. 15, front electrical connectors 244₁ (for example, ribbons, that cover and couple to the busbars) couple to the front contacts of cut solar cells 243₁ and 243₂); (b) front electrical connectors 244₂ provide electrical connection between metallization (front electrical contacts) coupled to the front surfaces of cut solar cells 243₃ and 243₄ (in FIG. 15, front electrical connectors 244₂ (for example, ribbons, that cover and couple to the busbars) couple to the front contacts of cut solar cells 243₃ and 243₄); (c) front electrical connectors 244₃ provide electrical connection between metallization (front electrical contacts) coupled to the front surfaces of solar cells 243₅ and 243₆ (in FIG. 15, front electrical connectors 244₃ (for example, ribbons, that cover and couple to the busbars) couple to the front contacts of cut solar cells 243₅ and 243₆); (d) front electrical connectors 244₄ provide electrical connection between metallization (front electrical contacts) coupled to the front surfaces of solar cells 243₇ and 243₈ (in FIG. 15, front electrical connectors 244₄ (for example, ribbons, that cover and couple to the busbars) (for example, ribbons, that cover and couple to the busbars) couple to the front contacts of cut solar cells 243₇ and 243₈); (e) back electrical connectors 244₅ provide electrical connection between metallization (back electrical contacts) coupled to the back surfaces of solar cells 243₂ and 243₃ (in FIG. 15, back electrical connectors 244₅ (for example, ribbons, that cover and couple to the busbars) couple to the back contacts of cut solar cells 243₂ and 243₃); (f) back electrical connectors 244₆ provide electrical connection between metallization (back electrical contacts) coupled to the back surfaces of solar cells 243₄ and 243₅ (in FIG. 15, back electrical connectors 244₆ (for example, ribbons, that cover and couple to the busbars) couple to the back contacts of cut solar cells 243₄ and 243₅); and (g) back electrical connectors 244₇ provide electrical connection between metallization (back electrical contacts) coupled to the back surfaces of solar cells 243₆ and 243₇ (in FIG. 15, back electrical connectors 244₇ (for example, ribbons, that cover and couple to the busbars) couple to the back contacts of cut solar cells 243₆ and 243₇).

In accordance with one or more such embodiments, the electrical connectors (i.e., the cell-to-cell, electrical connectors of metallizations (electrical contacts) which are connected in the above-described configuration) may be, for example and without limitation, ribbons, such as straight ribbons that do not extend through cell-to-cell gaps, or straight ribbons that do not extend into cell-to-cell gaps where, for example and without limitation, the ribbons extend completely over the busbars on the cells. Examples of suitable such ribbons were described above regarding embodiments in conjunction with “Full solar cells having electrical contacts (that include busbars) coupled to their front and back surfaces” and FIG. 11. The ribbons may be affixed to the metallizations (electrical contacts) by affixing them to the busbars by soldering, by use of conductive bonding, or by use of other known electrical bonding methods. In addition, the electrical connectors may be fabricated by affixing any one of a number of conducting tapes that are well known, such as conductive adhesive tape to the busbars. In further addition, the electrical connectors may be interconnectors 600 and 610 described above in conjunction with FIG. 40.

In accordance with one or more embodiments, gaps between two adjacent solar cell edges (i.e., gaps shown in FIGS. 14 and 15) can be in a range from about 5 mm to about 0.001 mm. In further addition, in accordance with one or more further embodiments, gaps between two adjacent cell edges can be reduced from 2 mm to less than 0.5 mm (for example, the gaps can be reduced to small dimensions such as, for example, 0.001 mm).

In accordance with one or more embodiments, solar modules like solar module 240 can be fabricated, for example and without limitation, by cutting the types of full solar cells described above (regarding embodiments in conjunction with “Full solar cells having electrical contacts (that include busbars) coupled to their front and back surfaces” and FIG. 11 (i.e., regarding p and n type solar cells)) into several pieces to provide cut cells. For example, a full solar cell can be cut into 3 pieces, 4 pieces, up to but not limited to 20 pieces. Then, the cut cells with opposite surface polarities can be connected in series as described above in conjunction with FIG. 15.

IV. Full Solar Cells and Wires Interconnect Electrical Contacts

In accordance with one or more embodiments, a solar module is fabricated wherein full solar cells having electrical contacts (for example and without limitation, metallization in the form of fingers) coupled to their front and back surfaces are electrically interconnected by wires coupled to the electrical contacts (i.e., the metallizations) thereof. A benefit of using wires is to reduce resistivity loss when collecting current from cell fingers.

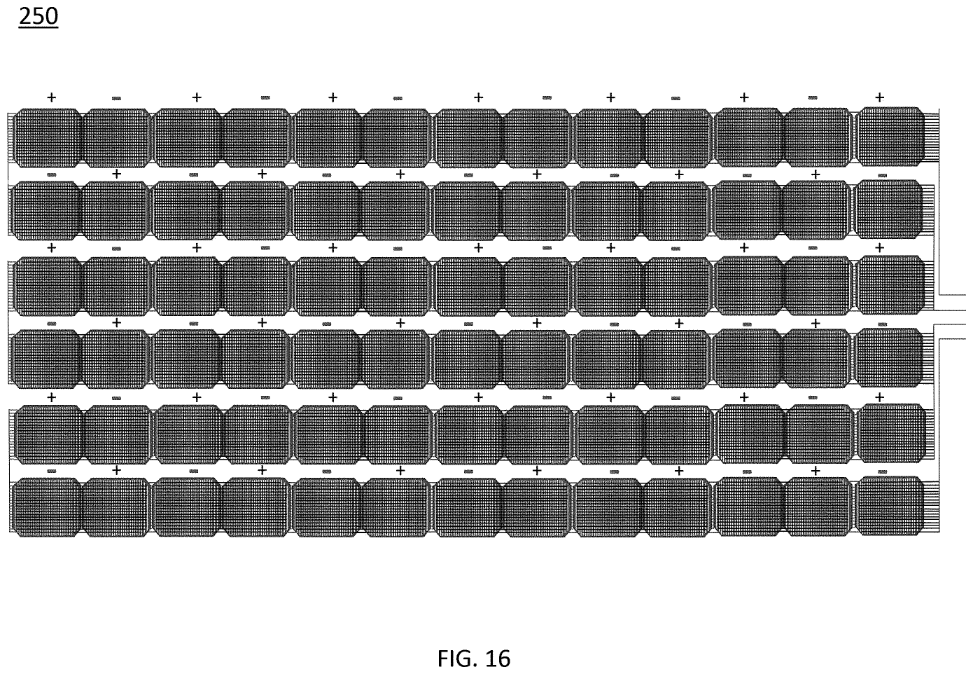

FIG. 16 shows a top view of solar module 250 (fabricated in accordance with one or more embodiments) comprised of full solar cells having electrical contacts coupled to their front and back surfaces which are interconnected by wires coupled to the electric contacts. FIG. 16 shows how the full solar cells are electrically connected, and the plus and minus signs show the electrical polarity of the electrical contacts coupled to the front surfaces of the full solar cells and the electrical polarity of charge carriers provided by the front surfaces of the solar cells when the solar cells are in operation. As can be seen from FIG. 16, in accordance with one or more embodiments, solar module 250 comprises six (6) strings of full solar cells having alternating negative and positive metallization (i.e., electrical contacts) coupled to the front surfaces of adjacent cells and, therefore, corresponding alternating positive and negative metallization (i.e., electrical contacts) coupled to the back surfaces of adjacent cells—where the solar cells are connected in series. In other words, in accordance with one or more such embodiments, solar module 250 comprises six (6) strings of full solar cells having alternating negative and positive front surfaces of adjacent cells and, therefore, corresponding alternating positive and negative back surfaces of adjacent cells—where the solar cells are connected in series.

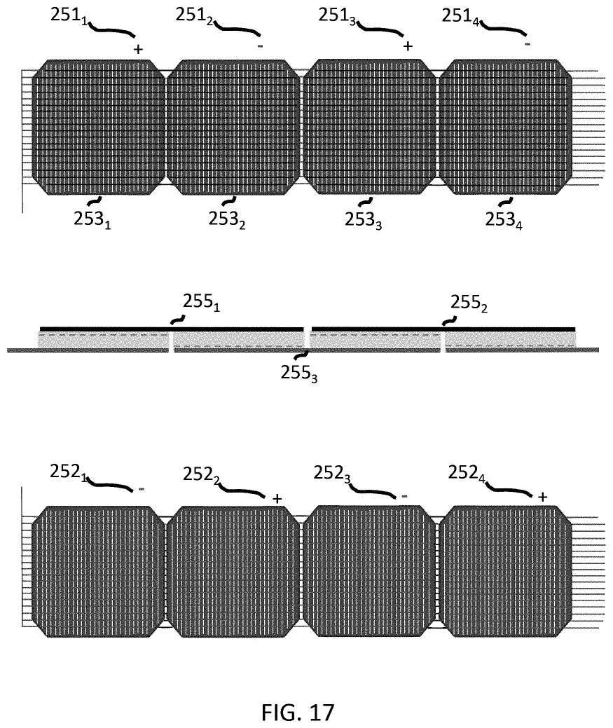

FIG. 17 shows: (a) a top view of a portion of the top side of solar module 250 shown in FIG. 16; (b) a cross-section of the portion of solar module 250 shown in FIG. 16 (where the electrical contacts are not shown in the cross-section to facilitate understanding); and (c) a bottom view of the portion of the back side of solar module 250 shown in FIG. 16, respectively—where the solar cells are connected in series.

In FIG. 17, in accordance with one or more such embodiments, plus signs 251₁ and 251₃ and minus signs 251₂ and 251₄ show the electrical polarity of metallization (i.e., front electrical contacts) coupled to the front surfaces of solar cells 253₁-253₄ (i.e., a negative metallization (negative front electrical contact) collects negative charge carriers from a negative front surface, which negative front surface provides negative charge carriers when the particular solar cell is in operation and a positive metallization (positive front electrical contact) collects positive charge carriers from a positive front surface, which positive front surface provides positive charge carriers when the particular solar cell is in operation). In addition, in accordance with one or more such embodiments, plus signs 252₂ and 252₄ and minus signs 252₁ and 252₃ show the electrical polarity of metallization (i.e., back electrical contacts) coupled to the back surfaces of solar cells 253₁-253₄ (i.e., a negative metallization (negative back electrical contact) collects negative charge carriers from a negative back surface, which negative back surface provides negative charge carriers when the particular solar cell is in operation and a positive metallization (positive back electrical contact) collects positive charge carriers from a positive back surface, which positive back surface provides positive charge carriers when the particular solar cell is in operation). In further addition, in accordance with one or more such embodiments: (a) front electrical connectors 255₁ provide electrical connection between electrical contacts coupled to the front surface of full solar cells 253₁ and 253₂ (in FIG. 17, front electrical connectors 255₁ (for example, wires, that cover and) couple to the front contacts of full solar cells 253₁ and 253₂); (b) front electrical connectors 255₂ provide electrical connection between electrical contacts coupled to the front surface of solar cells 253₃ and 253₄ (in FIG. 17, front electrical connectors 255₂ (for example, wires, that cover and) couple to the front contacts of full solar cells 253₃ and 253₄); and (c) back electrical connectors 255₃ provide electrical connection between electrical contacts coupled to the back surface of solar cells 253₂ and 253₃ (in FIG. 17, back electrical connectors 255₃ (for example, wires, that cover and) couple to the back contacts of full solar cells 253₂ and 253₃).

In accordance with one or more embodiments, solar modules like solar module 250 can be fabricated, for example and without limitation, using the types of full solar cells described above regarding embodiments in conjunction with “Full solar cells having electrical contacts (that include busbars) coupled to their front and back surfaces” and FIG. 11 (i.e., regarding p and n type solar cells)—where, in this case, the full cells are busbarless.

In accordance with one or more such embodiments, the front and back electrical connectors are wires coupled to the electrical contacts (i.e., the cell-to-cell, electrical connectors are wires which are connected in the above-described configuration) which may be, for example, wires, such as straight wires that do not extend through cell-to-cell gaps, or straight wires that do not extend into cell-to-cell gaps.

In accordance with one or more embodiments, the gaps between two adjacent solar cell edges (i.e., gaps shown in FIGS. 16 and 17) can be in a range from about 5 mm to about 0.001 mm. In further addition, in accordance with one or more further embodiments, gaps between two adjacent cell edges can be reduced from 2 mm to less than 0.5 mm (for example, the gaps can be reduced to small dimensions such as, for example, 0.001 mm).

In accordance with one or more such embodiments, using a technology from Meyer Burger Technology Ltd. (www.meyerburger.com), wherein straight wires (comprised of materials described above with respect to ribbons) are disposed on a plastic laminate. The length of the wires is sufficient to span at least the surfaces of two adjacent cells and the gap therebetween. Then, during a lamination process, pressure and heat are applied to the wire and cells so that a eutectic bond is formed between the wires and the electrical contacts (for example and without limitation, metallization in the form of fingers) coupled to the surfaces of the solar cells. This process is used to form electrical connections between electrical contacts coupled to the surfaces of solar cells in accordance with the configuration shown above with respect to FIG. 17.

V. Half Solar Cells and Wires Interconnect Electrical Contacts

In accordance with one or more embodiments, a solar module is fabricated wherein half solar cells having electrical contacts (for example and without limitation, metallization in the form of fingers) coupled to their front and back surfaces are electrically interconnected by wires coupled to the electrical contacts (i.e., the metallizations) thereof. A benefit of using wires is to reduce resistivity loss when collecting current from cell fingers.

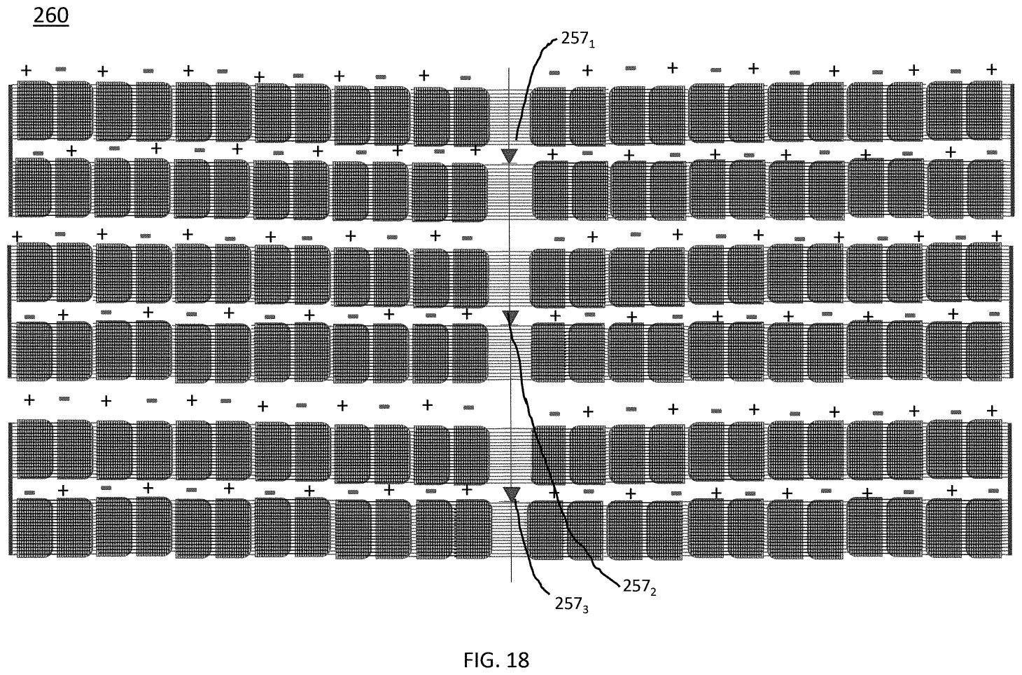

FIG. 18 shows a top view of solar module 260 (fabricated in accordance with one or more embodiments) comprised of half solar cells having electrical contacts coupled to their front and back surfaces which are interconnected by wires coupled to the electric contacts in a symmetrical module design having bypass diodes 257₁-257₃ in the middle thereof. FIG. 18 shows how the half solar cells are electrically connected, and the plus and minus signs show the electrical polarity of the electrical contacts coupled to the front surfaces of the half solar cells and the electrical polarity of charge carriers provided by the front surfaces of the solar cells when the solar cells are in operation. As can be seen from FIG. 18, in accordance with one or more embodiments, solar module 260 comprises twelve (12) strings of half solar cells having alternating negative and positive metallization (i.e., electrical contacts) coupled to the front surfaces of adjacent half cells and, therefore, corresponding alternating positive and negative metallization (i.e., electrical contacts) coupled to the back surfaces of adjacent cells—where the solar cells are connected in series. In other words, in accordance with one or more such embodiments, solar module 260 comprises twelve (12) strings of half solar cells having alternating negative and positive front surfaces of adjacent cells and, therefore, corresponding alternating positive and negative back surfaces of adjacent cells—where the solar cells are connected in series.

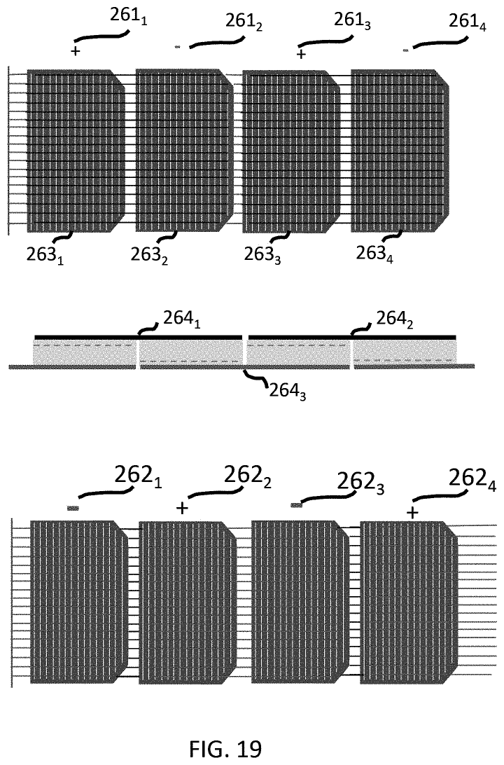

FIG. 19 shows: (a) a top view of a portion of the top side of solar module 260 shown in FIG. 18; (b) a cross-section of the portion of solar module 260 shown in FIG. 18 (where the electrical contacts are not shown in the cross-section to facilitate understanding); and (c) a bottom view of the portion of the back side of solar module 260 shown in FIG. 18, respectively—where the solar cells are connected in series.

In FIG. 19, in accordance with one or more such embodiments, plus signs 261₁ and 261₃ and minus signs 261₂ and 261₄ show the electrical polarity of metallization (i.e., front electrical contacts) coupled to the front surfaces of half solar cells 263₁-263₄ (i.e., a negative metallization (negative front electrical contact) collects negative charge carriers from a negative front surface, which negative front surface provides negative charge carriers when the particular solar cell is in operation and a positive metallization (positive front electrical contact) collects positive charge carriers from a positive front surface, which positive front surface provides positive charge carriers when the particular solar cell is in operation). In addition, in accordance with one or more such embodiments, plus signs 262₂ and 262₄ and minus signs 262₁ and 262₃ show the electrical polarity of metallization (i.e., back electrical contacts) coupled to the back surfaces of half solar cells 263₁-263₄ (i.e., a negative metallization (negative back electrical contact) collects negative charge carriers from a negative back surface, which negative back surface provides negative charge carriers when the particular solar cell is in operation and a positive metallization (positive back electrical contact) collects positive charge carriers from a positive back surface, which positive back surface provides positive charge carriers when the particular solar cell is in operation). In further addition, in accordance with one or more such embodiments: (a) front electrical connectors 264₁ provide electrical connection between electrical contacts coupled to the front surface of half solar cells 263₁ and 263₂ (in FIG. 19, front electrical connectors 264₁ (for example, wires, that cover and) couple to the front contacts of half solar cells 263₁ and 263₂); (b) front electrical connectors 264₂ provide electrical connection between electrical contacts coupled to the front surface of half solar cells 263₃ and 263₄ (in FIG. 19, front electrical connectors 264₂ (for example, wires, that cover and) couple to the front contacts of half solar cells 263₃ and 263₄); and (c) back electrical connectors 264₃ provide electrical connection between electrical contacts coupled to the back surface of half solar cells 263₂ and 263₃ (in FIG. 19, back electrical connectors 264₃ (for example, wires, that cover and) couple to the back contacts of half solar cells 263₂ and 263₃).

In accordance with one or more embodiments, solar modules like solar module 260 can be fabricated, for example and without limitation, using halves of the types of full solar cells described above regarding embodiments in conjunction with “Full solar cells having electrical contacts (that include busbars) coupled to their front and back surfaces” and FIG. 11 (i.e., regarding p and n type solar cells)—where, in this case, the cells are busbarless.

In accordance with one or more such embodiments, the front and back electrical connectors are wires coupled to the electrical contacts (i.e., the cell-to-cell, electrical connectors are wires which are connected in the above-described configuration) which may be, for example, wires, such as straight wires that do not extend through cell-to-cell gaps, or straight wires that do not extend into cell-to-cell gaps.

In accordance with one or more embodiments, the gaps between two adjacent solar cell edges (i.e., gaps shown in FIGS. 18 and 19) can be in a range from about 5 mm to about 0.001 mm. In further addition, in accordance with one or more further embodiments, gaps between two adjacent cell edges can be reduced from 2 mm to less than 0.5 mm (for example, the gaps can be reduced to small dimensions such as, for example, 0.001 mm).

In accordance with one or more embodiments, solar modules like solar module 260 can be fabricated using the methods described above with respect to solar module 250.

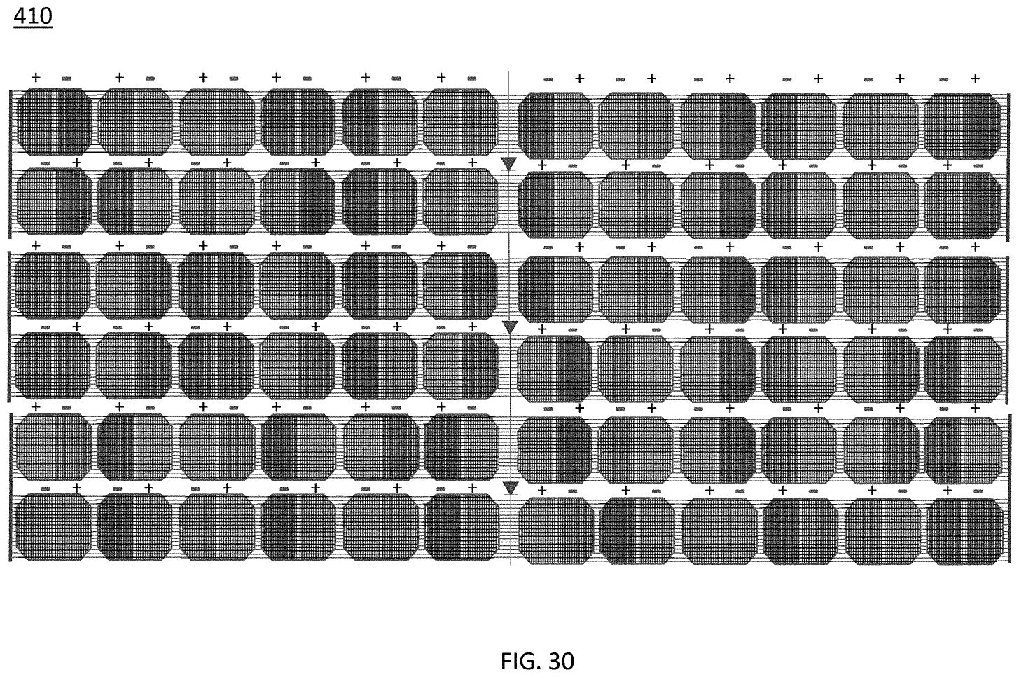

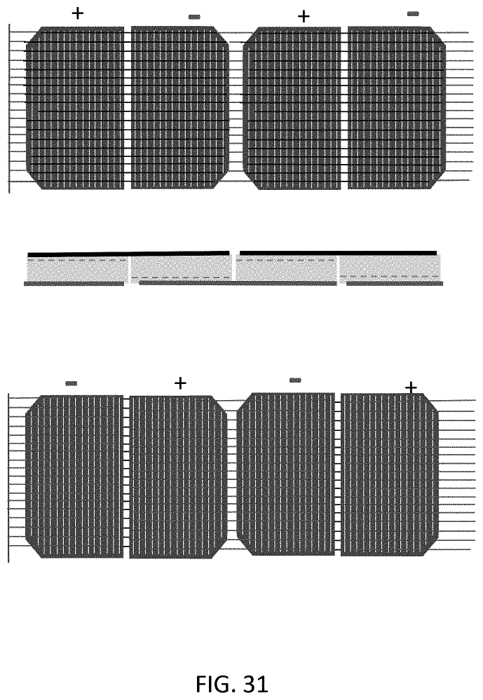

FIG. 30 shows a top view of solar module 410 comprised of twelve (12) strings of half solar cells wherein wires provide electrical interconnection in a symmetrical module design having bypass diodes in the middle thereof, which solar module 410 is fabricated in accordance with one or more further embodiments. FIG. 31 shows: (a) a top view of a portion of the top side of solar module 410 shown in FIG. 30; (b) a cross-section of the portion of solar module 410 shown in FIG. 30 (where the electrical contacts are not shown in the cross-section to facilitate understanding); and (c) a bottom view of the portion of the back side of solar module 410 shown in FIG. 30, respectively—where the solar cells are connected in series.

Solar module 410 and the manner in which the half solar cells comprising solar module 410 are connected is the same as for solar module 260 shown in FIG. 18 except for the relative orientation of alternating half solar cells to each other (as seen, for example, by comparing FIGS. 19 and 31).

VI. Cut Solar Cells and Wires Interconnect Electrical Contacts

In accordance with one or more embodiments, a solar module is fabricated wherein cut solar cells having electrical contacts (for example and without limitation, metallization in the form of fingers) coupled to their front and back surfaces are electrically interconnected by wires coupled to the electrical contacts (i.e., the metallizations) thereof. A benefit of using wires is to reduce resistivity loss when collecting current from cell fingers.

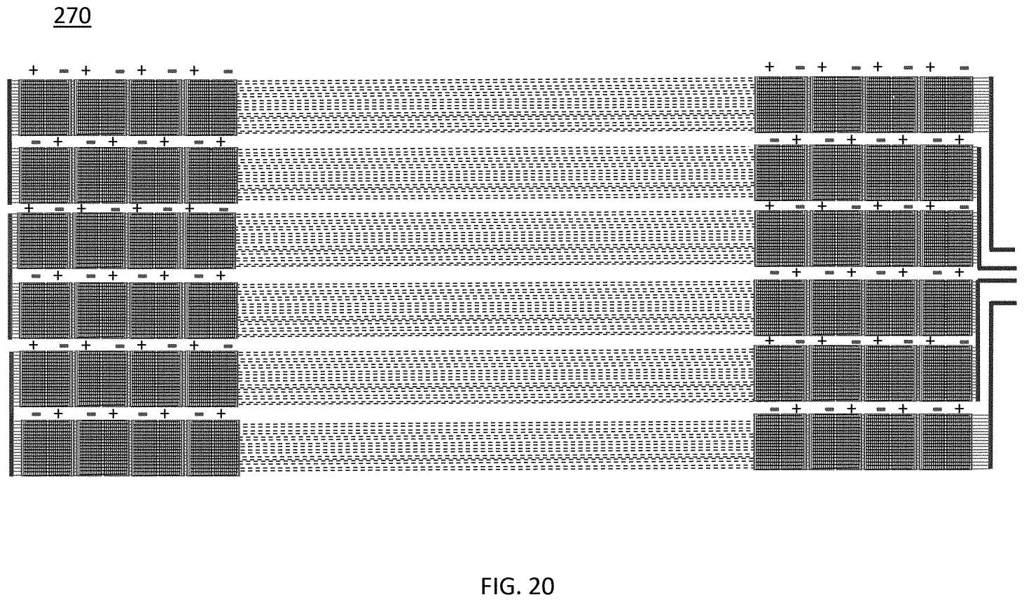

FIG. 20 shows a top view of solar module 270 (fabricated in accordance with one or more embodiments) comprised of cut solar cells having electrical contacts coupled to their front and back surfaces which are interconnected by wires coupled to the electric contacts. FIG. 20 shows how the cut solar cells are electrically connected, and the plus and minus signs show the electrical polarity of the electrical contacts coupled to the front surfaces of the solar cells and the electrical polarity of charge carriers provided by the front surfaces of the solar cells when the solar cells are in operation. As can be seen from FIG. 20, in accordance with one or more embodiments, solar module 270 comprises six (6) strings of cut solar cells having alternating negative and positive metallization (i.e., electrical contacts) coupled to the front surfaces of adjacent cut cells and, therefore, corresponding alternating positive and negative metallization (i.e., electrical contacts) coupled to the back surfaces of adjacent cells—where the solar cells are connected in series. In other words, in accordance with one or more such embodiments, solar module 270 comprises six (6) strings of cut solar cells having alternating negative and positive front surfaces of adjacent cells and, therefore, corresponding alternating positive and negative back surfaces of adjacent cells—where the solar cells are connected in series.

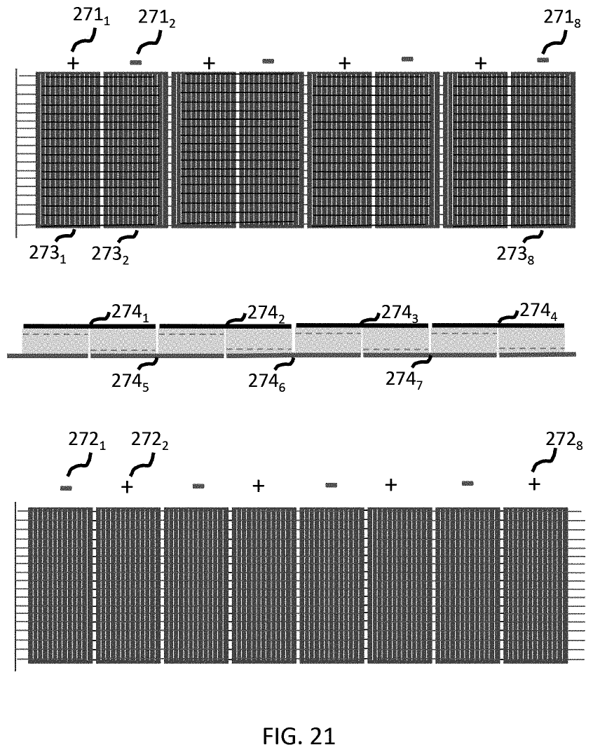

FIG. 21 shows: (a) a top view of a portion of the top side of solar module 270 shown in FIG. 20; (b) a cross-section of the portion of solar module 270 shown in FIG. 20 (where the electrical contacts are not shown in the cross-section to facilitate understanding); and (c) a bottom view of the portion of the back side of solar module 270 shown in FIG. 20, respectively—where the solar cells are connected in series.

In FIG. 21, in accordance with one or more such embodiments, plus signs 271₁, 271₃, 271₅ and 271₇ and minus signs 271₂, 271₄, 271₆, and 271₈ show the electrical polarity of metallization (i.e., front electrical contacts) coupled to the front surfaces of solar cells 273₁-273₈ (i.e., a negative metallization (i.e., negative front electrical contact) collects negative charge carriers from a negative front surface, which negative front surface provides negative charge carriers when the particular solar cell is in operation and a positive metallization (positive front electrical contact) collects positive charge carriers from a positive front surface, which positive front surface provides positive charge carriers when the particular solar cell is in operation). In addition, in accordance with one or more such embodiments, plus signs 272₂, 272₄, 272₆, and 272₈ and minus signs 272₁, 272₃, 272₅ and 272₇ show the electrical polarity of metallization (i.e., back electrical contacts) coupled to the back surfaces of solar cells 273₁-273₈ (i.e., a negative metallization (negative back electrical contact) collects negative charge carriers from a negative back surface, which negative back surface provides negative charge carriers when the particular solar cell is in operation and a positive metallization (positive back electrical contact) collects positive charge carriers from a positive back surface, which positive back surface provides positive charge carriers when the particular solar cell is in operation). In further addition, in accordance with one or more such embodiments: (a) front electrical connectors 274₁ provide electrical connection between electrical contacts coupled to the front surface of cut solar cells 273₁ and 273₂ (in FIG. 21, front electrical connectors 274₁ (for example, wires, that cover and) couple to the front contacts of cut solar cells 273₁ and 273₂); (b) front electrical connectors 274₂ provide electrical connection between electrical contacts coupled to the front surface of cut solar cells 273₃ and 273₄ (in FIG. 21, front electrical connectors 274₂ (for example, wires, that cover and) couple to the front contacts of cut solar cells 273₃ and 273₄); (c) front electrical connectors 274₃ provide electrical connection between electrical contacts coupled to the front surface of cut solar cells 273₅ and 273₆ (in FIG. 21, front electrical connectors 274₃ (for example, wires, that cover and) couple to the front contacts of cut solar cells 273₅ and 273₆); (d) front electrical connectors 274₄ provide electrical connection between electrical contacts coupled to the front surface of solar cells 273₇ and 273₈ (in FIG. 21, front electrical connectors 274₄ (for example, wires, that cover and) couple to the front contacts of cut solar cells 273₇ and 273₈); (e) back electrical connectors 274₅ provide electrical connection between electrical contacts coupled to the back surface of cut solar cells 273₂ and 273₃ (in FIG. 21, back electrical connectors 274₅ (for example, wires, that cover and) couple to the back contacts of cut solar cells 273₂ and 273₃); (f) back electrical connectors 274₆ provide electrical connection between electrical contacts coupled to the back surface of cut solar cells 273₄ and 273₅ (in FIG. 21, back electrical connectors 274₆ (for example, wires, that cover and) couple to the back contacts of cut solar cells 273₄ and 273₅); and (g) back electrical connectors 274₇ provide electrical connection between electrical contacts coupled to the back surface of cut solar cells 273₆ and 273₇ (in FIG. 21, back electrical connectors 274₇ (for example, wires, that cover and) couple to the back contacts of cut solar cells 273₆ and 273₇).

In accordance with one or more embodiments, solar modules like solar module 270 can be fabricated, for example and without limitation, by cutting into pieces the types of full solar cells described above regarding embodiments in conjunction with “Full solar cells having electrical contacts (that include busbars) coupled to their front and back surfaces” and FIG. 11 (i.e., regarding p and n type solar cells)—where, in this case, the cells are busbarless. For example, a full cell can be cut into 3 pieces, 4 pieces, up to but not limited to 20 pieces. Then, the cut cells having opposite polarities can be connected in series in the above-described manner in conjunction with FIG. 21.

In accordance with one or more such embodiments, the front and back electrical connectors are wires coupled to the electrical contacts (i.e., the cell-to-cell, electrical connectors are wires which are connected in the above-described configuration) which may be, for example, wires, such as straight wires that do not extend through cell-to-cell gaps, or straight wires that do not extend into cell-to-cell gaps.

In accordance with one or more embodiments, the gaps between two adjacent solar cell edges (i.e., gaps shown in FIGS. 20 and 21) can be in a range from about 5 mm to about 0.001 mm. In further addition, in accordance with one or more further embodiments, gaps between two adjacent cell edges can be reduced from 2 mm to less than 0.5 mm (for example, the gaps can be reduced to small dimensions such as, for example, 0.001 mm).

In accordance with one or more embodiments, solar modules like solar module 270 can be fabricated using the methods described above with respect to solar module 250.

VII. Mesh Metallization

In accordance with one or more embodiments, a solar cell comprises metallization (i.e., electrical contacts) that is coupled to the front and/or back surfaces of the solar cell, which metallization comprises a mesh metallization structure with electrical connection pads or a padless mesh metallization structure.

VII.A Mesh Metallization Structure with Electrical Connection Pads

FIG. 34 shows a plan view of a surface (front or back surface) of solar cell 500 that has an electrical contact comprised of a rectangular, mesh metallization structure with electrical connection pads 505₁-505₇ (disposed at or near an edge) coupled thereto in accordance with one or more embodiments; and FIG. 35 shows a plan view of a surface (front or back surface) of solar cell 510 that has an electrical contact comprised of a pseudo-circular web, mesh metallization structure with electrical connection pads 515₁-515₇ (disposed at or near an edge) coupled thereto in accordance with one or more embodiments. The electrical connection pads shown in FIGS. 34 and 35 may be screen printed onto the respective surface(s) of the solar cells using, for example and without limitation, Ag paste at the same time that the mesh metallization structures are screen printed onto the respective surface(s) of the solar cells. In particular, in accordance with one or more such embodiments: (a) the mesh metallization structure and the electrical connection pads are designed into a drawing; (b) the drawing is transferred onto a screen; and, then, (c) the whole pattern on the screen is printed onto a surface of the solar cell with, for example, Ag paste. As one of ordinary skill in the art will recognize, current generated by a solar cell will be collected by the mesh metallization structure and transmitted therefrom to the electrical connection pads.

In accordance with one or more further embodiments, the above-described mesh metallization structure can also be fabricated by screen printing with Cu paste, using printing stencils in conjunction with known printable metal materials, using jet printing with known ink-jettable metal materials (for example, Cu materials), and using known copper electroplating processes. For example, SunPower Corporation (web site www.sunpower.com) uses copper metallization processes in fabricating one or more of its solar cell products and Kaneka Corporation (web site www.kaneka-solar.com) has also developed copper metallization processes for fabricating one or more of its solar cell products.

In accordance with one or more embodiments, the mesh metallization structures may have a common feature, namely, that solar cell surface areas between metallizations are small. For example and without limitation, and in accordance with one or more embodiments, these areas may be less than 5 cm², less than 1 cm², less than 0.25 cm², less than 1 mm², less than 0.5 mm², or less than 0.1 mm². Advantageously, in accordance with one or more of the above-described embodiments, the thickness of such screen printed, mesh metallization structures used to fabricate solar cells can be reduced significantly, thereby reducing the amount of, for example, Ag paste used to fabricate solar modules.

VII.B Padless Mesh Metallization Structure

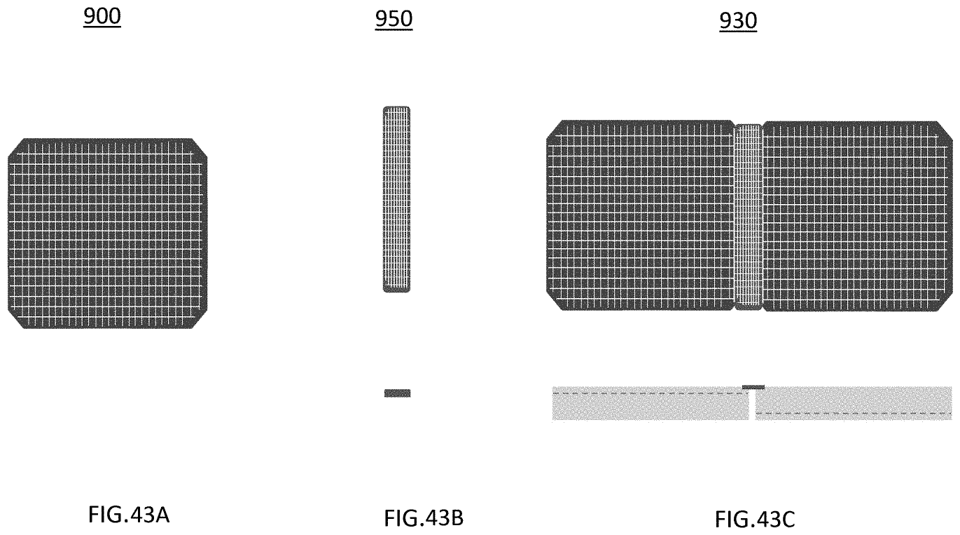

FIG. 43A shows a plan view of a surface (front or back surface) of solar cell 900 that has an electrical contact comprised of a rectangular, padless, mesh metallization structure coupled thereto in accordance with one or more embodiments. The padless mesh metallization structure shown in FIG. 43A may have the form of the mesh metallization structures shown in FIGS. 34 and 35, albeit without the pads. Further, the padless mesh metallization structure shown in FIG. 43A may be fabricated using the methods described above regarding the fabrication of mesh metallization structures shown in FIGS. 34 and 35, albeit without forming pads.

VIII. Solar Cell Electrical Connection by Free-Standing Metallic Article

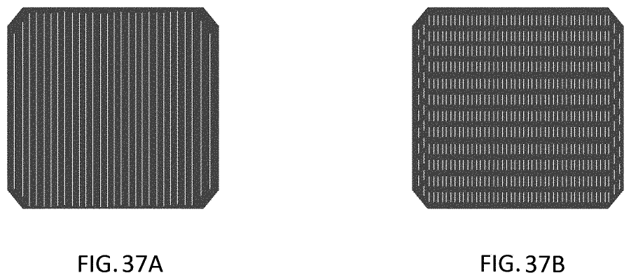

In accordance with one or more embodiments, solar cells can be interconnected using a “free-standing metallic article.” FIG. 36 shows free-standing metallic article 550 that can be coupled (for example and without limitation, by soldering or by use of conductive bonding) to a front and/or back electrical contact of a solar cell. For example, the free-standing metallic article may be coupled to an electrical contact (such as the metallizations shown in FIGS. 37A and 37B) coupled to their front surfaces and/or back surfaces, which metallizations may be screen printed. The method of fabricating such free-standing metallic articles and the method of affixing such free-standing metallic articles to the metallization structures can be provided, for example, by technology from Merlin Solar Technologies, Inc. (“MSTI”) (web site www.merlinsolar.com refers to U.S. Pat. No. 9,054,238 (the '238 patent) and U.S. Pat. No. 8,936,709 (the '709 patent) as relating to this technology). As such, the '228 patent and the '709 patent are incorporated by reference herein as to their entirety. In this approach, since there are no busbars and the height of fingers can be reduced, the use Ag paste can also be reduced.

IX.A Full Solar Cells Having Electrical Contacts (that Comprise Mesh Metallization Structures with Electrical Connection Pads) Coupled to their Front and Back Surfaces

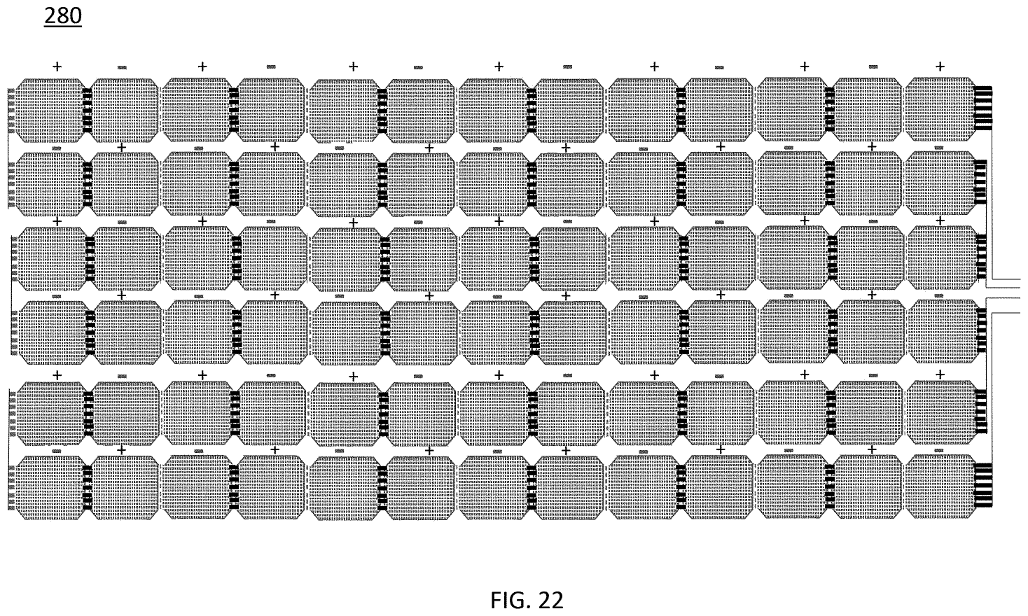

In accordance with one or more embodiments, a solar module is fabricated using full solar cells having electrical contacts (comprised of a mesh metallization structure with electrical connection pads) coupled to their front and back surfaces (for example, refer to FIGS. 34 and 35 discussed above). FIG. 22 shows a top view of solar module 280 (fabricated in accordance with one or more embodiments) comprised of full solar cells having electrical contacts comprised of mesh metallization structures with electrical connection pads coupled to the front and back surfaces. As can be seen from FIG. 22, in accordance with one or more embodiments, solar module 280 comprises six (6) strings of full solar cells having alternating negative and positive metallization (i.e., electrical contacts) coupled to the front surfaces of adjacent cells and, therefore, corresponding to alternating positive and negative metallization (i.e., electrical contacts) coupled to the back surfaces of adjacent cells—where the solar cells are connected in series. In other words, in accordance with one or more such embodiments, solar module 280 comprises six (6) strings of full solar cells having alternating negative and positive front surfaces of adjacent cells and, therefore, corresponding alternating positive and negative back surfaces of adjacent cells—where the solar cells are connected in series.

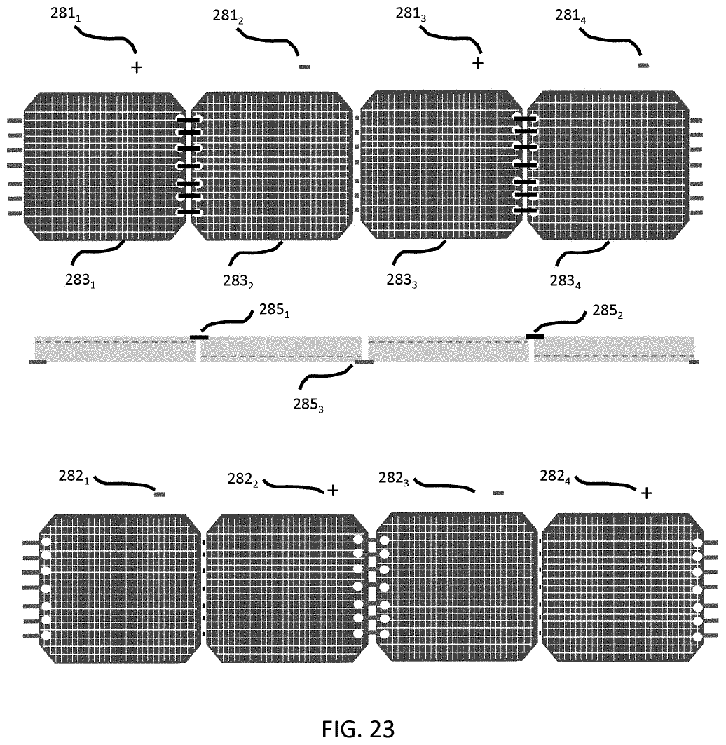

FIG. 23 shows: (a) a top view of a portion of the top side of solar module 280 shown in FIG. 22; (b) a cross-section of the portion of solar module 280 shown in FIG. 22 (where the electrical contacts are not shown in the cross-section to facilitate understanding); and (c) a bottom view of the portion of the back side of solar module 280 shown in FIG. 22, respectively—where the solar cells are connected in series.

In FIG. 23, in accordance with one or more such embodiments, plus signs 281₁ and 281₃ and minus signs 281₂ and 281₄ show the electrical polarity of metallization (i.e., front electrical contacts) coupled to the front surfaces of solar cells 283₁-283₄ (i.e., a negative metallization (negative front electrical contact) collects negative charge carriers from a negative front surface, which negative front surface provides negative charge carriers when the particular solar cell is in operation and a positive metallization (positive front electrical contact) collects positive charge carriers from a positive front surface, which positive front surface provides positive charge carriers when the particular solar cell is in operation). In addition, in accordance with one or more such embodiments, plus signs 282₂ and 282₄ and minus signs 282₁ and 282₃ show the electrical polarity of metallization (i.e., back electrical contacts) coupled to the back surfaces of solar cells 283₁-283₄ (i.e., a negative metallization (negative back electrical contact) collects negative charge carriers from a negative back surface, which negative back surface provides negative charge carriers when the particular solar cell is in operation and a positive metallization (positive back electrical contact) collects positive charge carriers from a positive back surface, which positive back surface provides positive charge carriers when the particular solar cell is in operation). In further addition, in accordance with one or more such embodiments: (a) front electrical connectors 285₁ connect electrical connection pads on the right-hand edge of the front surface of solar cell 283₁ to electrical connection pads on the left-hand edge of the front surface of solar cell 283₂; (b) front electrical connectors 285₂ connect electrical connection pads on the right-hand edge of the front surface of solar cell 283₃ to electrical connection pads on the left-hand side of the front surface of solar cell 283₄; and (c) back electrical connectors 285₃ connect electrical connection pads on the right-hand edge of the back surface of solar cell 283₂ to electrical connection pads on the left-hand side of the back surface of solar cell 283₃.

In accordance with one or more such embodiments, the electrical connectors (i.e., the cell-to-cell, electrical connectors of electrical connection pads which are connected in the above-described configuration) may be, for example and without limitation, ribbons, such as straight ribbons that do not extend through cell-to-cell gaps, or straight ribbons that do not extend into cell-to-cell gaps. Examples of suitable such ribbons were described above in conjunction with “Full solar cells having electrical contacts (that include busbars) coupled to their front and back surfaces” and FIG. 11. The ribbons may be affixed to electrical connection pads by soldering, by use of conductive bonding, or by use of other suitable electrical bonding methods. In addition, the electrical connectors may be any one of a number of conducting tapes that are well known, such as conductive adhesive tape. In accordance with one or more such embodiments, the ribbons may be soldered to electrical connection pads which are solder pads disposed close to the cell's edge. For example and without limitation, such solder pads can be round (having, for example and without limitation, a 2 mm diameter) or they can be square (having, for example and without limitation, a 2 mm side dimension). In addition, the pads can be placed, for example and without limitation, as close as 1 mm or as close as 0.5 mm or as close as 0.1 mm away from a cell's edge. In further addition, the electrical connectors may be interconnectors 600 or 610 described above in conjunction with FIG. 40.

In accordance with one or more embodiments, gaps between two adjacent solar cell edges (i.e., gaps shown in FIGS. 22 and 23) can be in a range from about 5 mm to about 0.001 mm. In further addition, in accordance with one or more further embodiments, gaps between two adjacent cell edges can be reduced from 2 mm to less than 0.5 mm (for example, the gaps can be reduced to small dimensions such as, for example, 0.001 mm).

In accordance with one or more embodiments, solar modules like solar module 280 can be fabricated, for example and without limitation, using the types of full solar cells described above regarding embodiments in conjunction with “Full solar cells having electrical contacts (that include busbars) coupled to their front and back surfaces” and FIG. 11 (i.e., regarding p and n type solar cells)—where, in this case, the full cells have mesh metallization structures with electrical connection pads.

IX.B Half Solar Cells Having Electrical Contacts (that Comprise Mesh Metallization Structures with Electrical Connection Pads) Coupled to their Front and Back Surfaces

In accordance with one or more embodiments, a solar module is fabricated using half solar cells having electrical contacts (comprised of a mesh metallization structure with electrical connection pads) coupled to their front and back surfaces (for example, refer to FIGS. 34 and 35 discussed above). FIG. 24 shows a top view of solar module 290 (fabricated in accordance with one or more embodiments) comprised of half solar cells having electrical contacts comprised of mesh metallization structures with electrical connection pads coupled to the front and back surfaces. As can be seen from FIG. 24, in accordance with one or more embodiments, solar module 290 comprises twelve (12) strings of half solar cells having alternating negative and positive metallization (i.e., electrical contacts) coupled to the front surfaces of adjacent cells and, therefore, corresponding alternating positive and negative metallization (i.e., electrical contacts) coupled to the back surfaces of adjacent cells—where the solar cells are connected in series. In other words, in accordance with one or more such embodiments, solar module 290 comprises twelve (12) strings of half solar cells having alternating negative and positive front surfaces of adjacent cells and, therefore, corresponding alternating positive and negative back surfaces of adjacent cells—where the solar cells are connected in series.

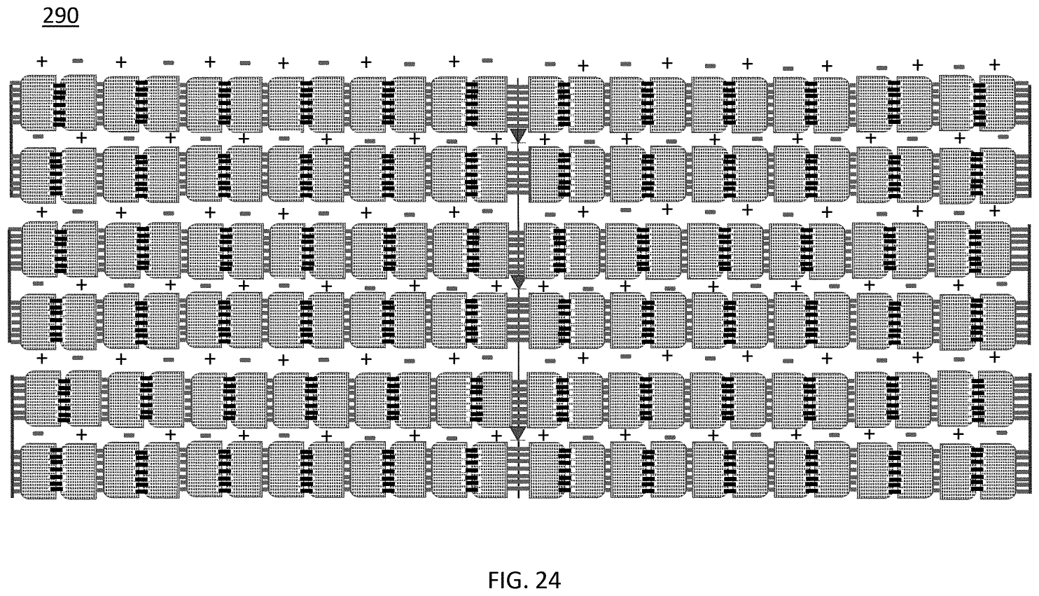

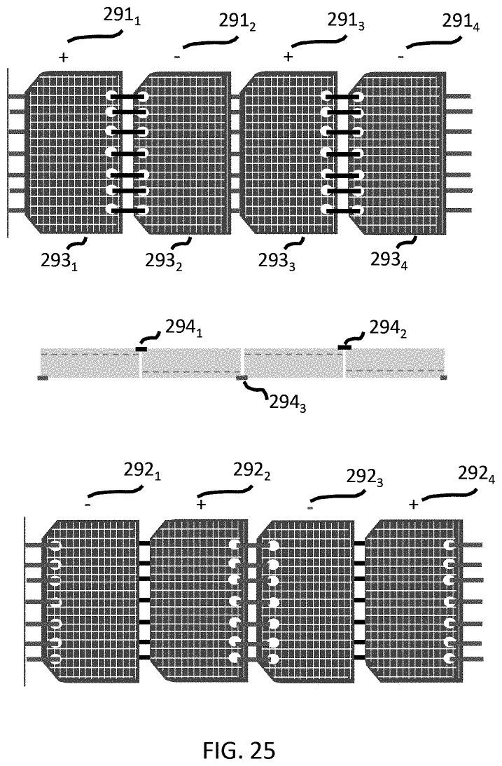

FIG. 25 shows: (a) a top view of a portion of the top side of solar module 290 shown in FIG. 24; (b) a cross-section of the portion of solar module 290 shown in FIG. 24 (where the electrical contacts are not shown in the cross-section to facilitate understanding); and (c) a bottom view of the portion of the back side of solar module 290 shown in FIG. 24, respectively—where the solar cells are connected in series.

In FIG. 25, in accordance with one or more such embodiments, plus signs 291₁ and 291₃ and minus signs 291₂ and 291₄ show the electrical polarity of metallization (i.e., front electrical contacts) coupled to the front surfaces of solar cells 293₁-29₄ (i.e., a negative metallization (negative front electrical contact) collects negative charge carriers from a negative front surface, which negative front surface provides negative charge carriers when the particular solar cell is in operation and a positive metallization (positive front electrical contact) collects positive charge carriers from a positive front surface, which positive front surface provides positive charge carriers when the particular solar cell is in operation). In addition, in accordance with one or more such embodiments, plus signs 292₂ and 292₄ and minus signs 292₁ and 292₃ show the electrical polarity of metallization (i.e., back electrical contacts) coupled to the back surfaces of solar cells 293₁-293₄ (i.e., a negative metallization (negative back electrical contact) collects negative charge carriers from a negative back surface, which negative back surface provides negative charge carriers when the particular solar cell is in operation and a positive metallization (positive back electrical contact) collects positive charge carriers from a positive back surface, which positive back surface provides positive charge carriers when the particular solar cell is in operation). In further addition, in accordance with one or more such embodiments: (a) front electrical connectors 294₁ connect electrical connection pads on the right-hand edge of the front surface of solar cell 293₁ to electrical connection pads on the left-hand side of the front surface of solar cell 293₂; (b) front electrical connectors 294₂ connect electrical connection pads on the right-hand edge of the front surface of solar cell 293₃ to electrical connection pads on the left-hand side of the front surface of solar cell 293₄; and (c) back electrical connectors 285₃ connect electrical connection pads on the right-hand edge of the back surface of solar cell 293₂ to electrical connection pads on the left-hand side of the back surface of solar cell 293₃.

In accordance with one or more such embodiments, the front and back electrical connectors (i.e., the cell-to-cell, electrical connectors of electrical connection pads which are connected in the above-described configuration) may be, for example and without limitation, ribbons, such as straight ribbons that do not extend through cell-to-cell gaps, or straight ribbons that do not extend into cell-to-cell gaps. Examples of suitable such ribbons were described above in conjunction with “Full solar cells having electrical contacts (that include busbars) coupled to their front and back surfaces” and FIG. 11. The ribbons may be affixed to busbars by soldering, by use of conductive bonding, or by use of other suitable electrical bonding methods. In addition, the electrical connectors may be any one of a number of conducting tapes that are well known, such as conductive adhesive tape. In accordance with one or more such embodiments, the ribbons may be soldered to electrical connection pads which are solder pads disposed close to the cell's edge. For example and without limitation, such solder pads can be round (having, for example and without limitation, a 2 mm diameter) or they can be square (having, for example and without limitation, a 2 mm side dimension). In addition, the pads can be placed, for example and without limitation, as close as 1 mm or as close as 0.5 mm or as close as 0.1 mm away from a cell's edge. In further addition, the electrical connectors may be interconnectors 600 or 610 described above in conjunction with FIG. 40.

In accordance with one or more embodiments, gaps between two adjacent solar cell edges (i.e., gaps shown in FIGS. 24 and 25) can be in a range from about 5 mm to about 0.001 mm. In further addition, in accordance with one or more further embodiments, gaps between two adjacent cell edges can be reduced from 2 mm to less than 0.5 mm (for example, the gaps can be reduced to small dimensions such as, for example, 0.001 mm).

In accordance with one or more embodiments, solar modules like solar module 290 can be fabricated, for example and without limitation, using halves of the types of full solar cells described above regarding embodiments in conjunction with “Full solar cells having electrical contacts (that include busbars) coupled to their front and back surfaces” and FIG. 11 (i.e., regarding p and n type solar cells)—where, in this case, the half cells have mesh metallization structures with electrical connection pads.

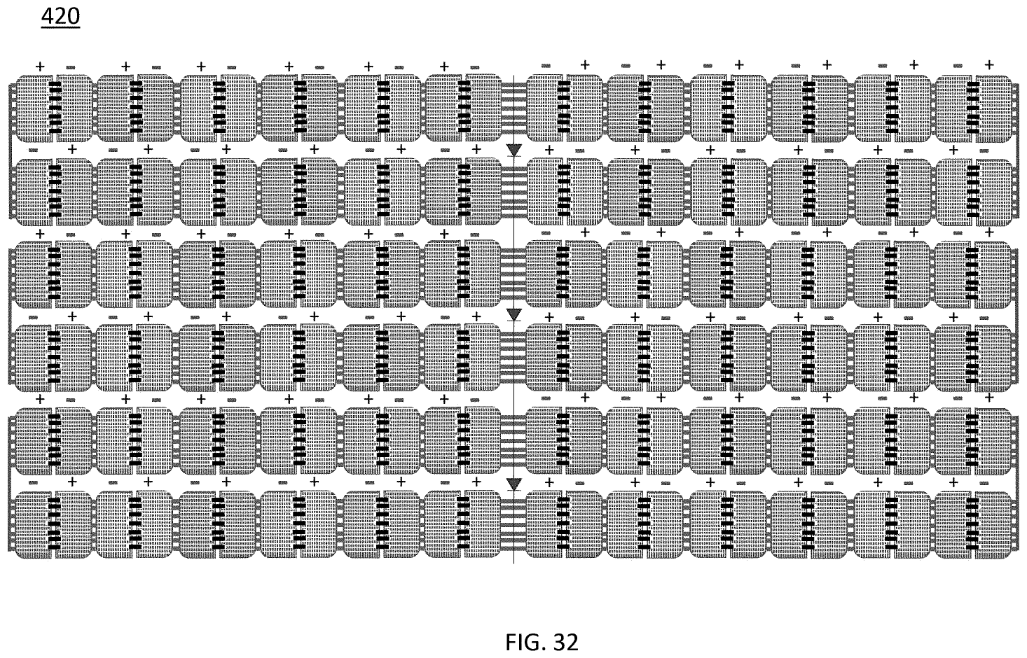

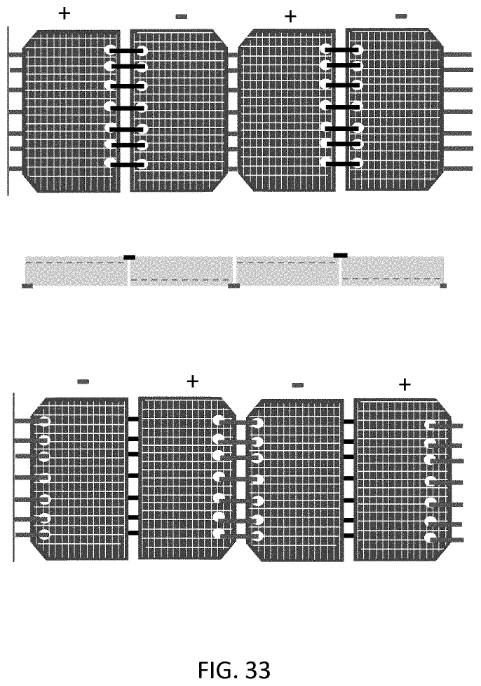

FIG. 32 shows a top view of solar module 420 (fabricated in accordance with one or more further embodiments) comprised of twelve (12) strings of half solar cells having electrical contacts comprised of metal metallization structures with electrical connection pads coupled to the front and back surfaces in a symmetrical module design having bypass diodes in the middle thereof. FIG. 33 shows: (a) a top view of a portion of the top side of solar module 420 shown in FIG. 32; (b) a cross-section of the portion of solar module 420 shown in FIG. 32 (where the electrical contacts are not shown in the cross-section to facilitate understanding); and (c) a bottom view of the portion of the back side of solar module 420 shown in FIG. 32, respectively—where the solar cells are connected in series.

Solar module 420 and the manner in which the half cells comprising solar module 410 are connected is the same that for solar module 290 shown in FIG. 24 except for the relative orientation of alternating half solar cells to each other (as seen, for example, by comparing FIGS. 25 and 33).

IX.C Cut Solar Cells Having Electrical Contacts (that Comprise Mesh Metallization Structures with Electrical Connection Pads) Coupled to their Front and Back Surfaces

In accordance with one or more embodiments, a solar module is fabricated using cut solar cells having electrical contacts (comprised of a mesh metallization structure with electrical connection pads) coupled to their front and back surfaces (for example, refer to FIGS. 34 and 35 discussed above). FIG. 26 shows a top view of solar module 300 (fabricated in accordance with one or more embodiments) comprised of cut solar cells having electrical contacts comprised of mesh metallization structures with electrical connection pads coupled to the front and back surfaces. As can be seen from FIG. 26, in accordance with one or more embodiments, solar module 300 comprises six (6) strings of cut solar cells having alternating negative and positive metallization (i.e., electrical contacts) coupled to the front surfaces of adjacent cells and, therefore, corresponding alternating positive and negative metallization (i.e., electrical contacts) coupled to the back surfaces of adjacent cells. —where the solar cells are connected in series. In other words, in accordance with one or more such embodiments, solar module 300 comprises six (6) strings of cut solar cells having alternating negative and positive front surfaces of adjacent cells and, therefore, corresponding alternating positive and negative back surfaces of adjacent cells—where the solar cells are connected in series.

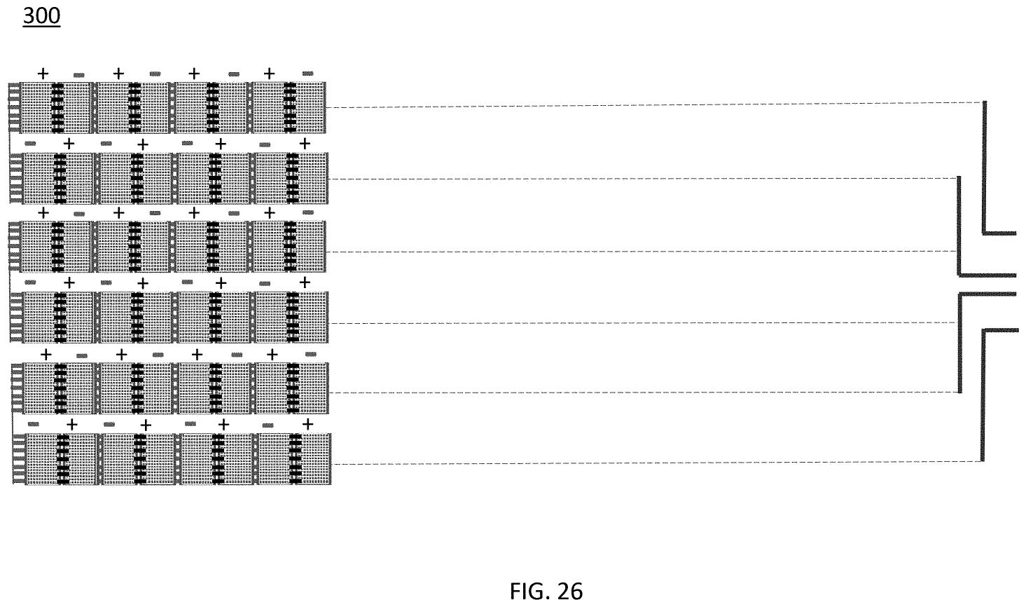

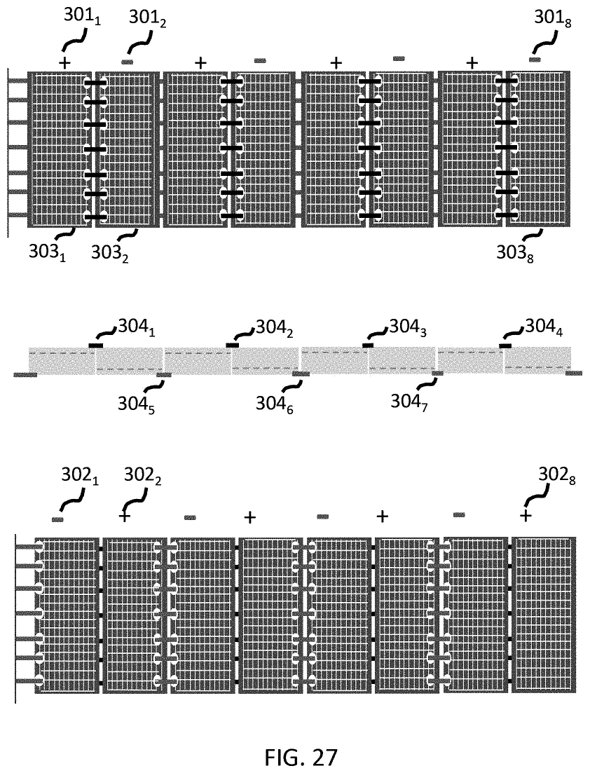

FIG. 27 shows: (a) a top view of a portion of the top side of solar module 300 shown in FIG. 26; (b) a cross-section of the portion of solar module 300 shown in FIG. 26 (where the electrical contacts are not shown in the cross-section to facilitate understanding); and (c) a bottom view of the portion of the back side of solar module 300 shown in FIG. 26, respectively—where the solar cells are connected in series.

In FIG. 27, in accordance with one or more such embodiments, plus signs 301₁, 301₃, 301₅ and 301₇ and minus signs 301₂, 301₄, 301₆, and 301₈ show the electrical polarity of metallization (i.e., front electrical contacts) coupled to the front surfaces of solar cells 303₁-303₈ (i.e., a negative metallization (negative front electrical contact) collects negative charge carriers from a negative front surface, which negative front surface provides negative charge carriers when the particular solar cell is in operation and a positive metallization (positive front electrical contact) collects positive charge carriers from a positive front surface, which positive front surface provides positive charge carriers when the particular solar cell is in operation). In addition, in accordance with one or more such embodiments, plus signs 302₂, 302₄, 302₆, and 302₈ and minus signs 302₁, 302₃, 302₅ and 307₇ show the electrical polarity of metallization (i.e., back electrical contacts) coupled to the back surfaces of solar cells 303₁-303₈ (i.e., a negative metallization (negative back electrical contact) collects negative charge carriers from a negative back surface, which negative back surface provides negative charge carriers when the particular solar cell is in operation and a positive metallization (positive back electrical contact) collects positive charge carriers from a positive back surface, which positive back surface provides positive charge carriers when the particular solar cell is in operation). In further addition, in accordance with one or more such embodiments: (a) front electrical connectors 304₁ connect electrical connection pads on the right-hand edge of the front surface of solar cell 303₁ to electrical connection pads on the left-hand edge of the front surface of solar cell 303₂; (b) front electrical connectors 304₂ connect electrical connection pads on the right-hand edge of the front surface of solar cell 303₃ to electrical connection pads on the left-hand edge of the front surface of solar cell 303₄; (c) front electrical connectors 304₃ connect electrical connection pads on the right-hand edge of the front surface of solar cell 303₅ to electrical connection pads on the left-hand edge of the front surface of solar cell 303₆; (d) front electrical connectors 304₄ connect electrical connection pads on the right-hand edge of the front surface of solar cell 303₇ to electrical connection pads on the left-hand edge of the front surface of solar cell 303₈; (e) back electrical connectors 304₅ connect electrical connection pads on the right-hand edge of the back surface of solar cell 303₂ to electrical connection pads on the left-hand edge of the back surface of solar cell 303₃; and (f) back electrical connectors 304₆ connect electrical connection pads on the right-hand edge of the back surface of solar cell 303₅ to electrodes on the left-hand edge of the back surface of solar cell 303₆.

In accordance with one or more such embodiments, the front and back electrical connectors (i.e., the cell-to-cell, electrical connectors of electrical connection pads which are connected in the above-described configuration) may be, for example and without limitation, ribbons, such as straight ribbons that do not extend through cell-to-cell gaps, or straight ribbons that do not extend into cell-to-cell gaps. Examples of suitable such ribbons were described above in conjunction with “Full solar cells having electrical contacts (that include busbars) coupled to their front and back surfaces” and FIG. 11. The ribbons may be affixed to busbars by soldering, by use of conductive bonding, or by use of other suitable electrical bonding methods. In addition, the electrical connectors may be any one of a number of conducting tapes that are well known, such as conductive adhesive tape. In accordance with one or more such embodiments, the ribbons may be soldered to electrical connection pads which are solder pads disposed close to the cell's edge. For example and without limitation, such solder pads can be round (having, for example and without limitation, a 2 mm diameter) or they can be square (having, for example and without limitation, a 2 mm side dimension). In addition, the pads can be placed, for example and without limitation, as close as 1 mm or as close as 0.5 mm or as close as 0.1 mm away from a cell's edge. In further addition, the electrical connectors may be interconnectors 600 or 610 described above in conjunction with FIG. 40.

In accordance with one or more embodiments, the gaps between two adjacent solar cell edges (i.e., gaps shown in FIGS. 26 and 27) can be in a range from about 5 mm to about 0.001 mm. In further addition, in accordance with one or more further embodiments, gaps between two adjacent cell edges can be reduced from 2 mm to less than 0.5 mm (for example, the gaps can be reduced to small dimensions such as, for example, 0.001 mm).

In accordance with one or more embodiments, solar modules like solar module 300 can be fabricated, for example and without limitation, using pieces of the types of full solar cells described above regarding embodiments in conjunction with “Full solar cells having electrical contacts (that include busbars) coupled to their front and back surfaces” and FIG. 11 (i.e., regarding p and n type solar cells)—where, in this case, the cut cells have mesh metallization structures with electrical connection pads.

X. Full Solar Cells (or Half Solar Cells or Cut Solar Cells) Having Electrical Contacts (that Comprise Padless Mesh Metallization Structures) Coupled to Front and Back Surfaces

In accordance with one or more embodiments, a solar module is fabricated using full solar cells (or half solar cells or cut solar cells) having electrical contacts (comprised of a padless mesh metallization structure) coupled to their front and back surfaces (for example, refer to FIGS. 34 and 35, albeit without the pads) where full solar cells (or half solar cells or cut solar cells) are electrically connected by wire mesh. FIG. 43B shows interconnector wire mesh 950 that is fabricated on accordance with one or more embodiments. In accordance with one or more embodiments, the wires can be arranged so that the wires are parallel or they can be arranged into a mesh. In accordance with one or more embodiments, the wires of interconnector wire mesh 950 are disposed on a plastic laminate, and the width of interconnector wire mesh 950 is sufficient to span the gap between two adjacent cells and overlap edges of the padless mesh metallization structures on the two adjacent cells, where the length of the overlap is sufficient to ensure reliable mechanical and electrical interconnection (one of ordinary skill in the art can readily determine suitable lengths without undue experimentation). Interconnection between adjacent cells is made during a lamination process. During this lamination process, pressure and heat are applied to the wire mesh and the overlap region of the cells so that a eutectic bond is formed between the wire mesh and the padless mesh metallization structures disposed on the surfaces of the solar cells. Refer to FIG. 43C which shows a top view of the front surfaces of two solar cells like solar cell 900 that are interconnected by wire mesh 950 in accordance with one or more embodiments and a cross-section of the interconnected solar cells (where the electrical contacts are not shown in the cross-section to facilitate understanding).

In accordance with one or more embodiments, a solar module comprises full solar cells (or half solar cells or cut solar cells) having alternating negative and positive metallization (i.e., electrical contacts) coupled to the front surfaces of adjacent cells and, therefore, corresponding alternating positive and negative metallization (i.e., electrical contacts) coupled to the back surfaces of adjacent cells—where the solar cells are connected in series. In other words, in accordance with one or more such embodiments, the solar module comprises full solar cells (or half solar cells or cut solar cells) having alternating negative and positive front surfaces (which negative front surfaces provide negative charge carriers when the particular solar cell is in operation and which positive front surface provides positive charge carriers when the particular solar cell is in operation) of adjacent cells and, therefore, corresponding alternating positive and negative back surfaces of adjacent cells—where the solar cells are connected in series.

In accordance with one or more embodiments, gaps between two adjacent full solar cell (or half solar cells or cut solar cells) edges can be in a range from about 5 mm to about 0.001 mm. In further addition, in accordance with one or more further embodiments, gaps between two adjacent cell edges can be reduced from 2 mm to less than 0.5 mm (for example, the gaps can be reduced to small dimensions such as, for example, 0.001 mm).

In accordance with one or more embodiments, such solar modules can be fabricated, for example and without limitation, using the types of full solar cells described above regarding embodiments in conjunction with “Full solar cells having electrical contacts (that include busbars) coupled to their front and back surfaces” and FIG. 11 (i.e., regarding p and n type solar cells)—where, in this case, the full cells (or half solar cells or cut solar cells) have padless mesh metallization structures.

XI. Full, Half and Cut Solar Cells and a Free-Standing Metallic Article Interconnects Electrical Contacts

In accordance with one or more embodiments, a solar module is fabricated wherein full solar cells, half solar cells or cut solar cells having electrical contacts coupled to their front and back surfaces are electrically interconnected by free-standing metallic articles coupled to the electrical contacts thereof. In particular, in accordance with one or more embodiments, the solar cell has a metallization structure coupled to its front and back surfaces and a portion of a free-standing metallic article is coupled to the metallization structure (where the metallization structure forms an electrical contact). Further, another portion of the free-standing metallic article connects an adjacent solar cell in the same configuration described above in conjunction with FIG. 17 where full solar cells were connected by wires and where solar cells having a front positive surface and solar cells having a front negative surface are adjacent to each other—where the solar cells are connected in series.

In accordance with one or more such embodiments, the length of the free-standing metallic article is sufficient to span for example and without limitation, at least the metallization structures coupled to the surfaces of two adjacent cells and a gap between the two adjacent cells. As a result, electrical contacts coupled to the surfaces of adjacent solar cells are electrically connected in accordance with a configuration like that shown above with respect to FIG. 17 where solar cells having alternate polarity of their top surfaces are connected—where the solar cells are connected in series. Thus, in accordance with one or more embodiments, a solar module comprises full solar cells or half solar cells or cut solar cells having alternating negative and positive electrical contacts coupled to the front surfaces of adjacent cells and, therefore, corresponding alternating positive and negative electrical contacts coupled to the back surfaces of adjacent cells—where the solar cells are connected in series. In other words, in accordance with one or more such embodiments, a solar module comprises solar cells having alternating negative and positive front surfaces of adjacent cells and, therefore, corresponding alternating positive and negative back surfaces of adjacent cells—where the solar cells are connected in series.

In accordance with one or more embodiments, such solar modules can be fabricated, for example and without limitation, using the types of solar cells described above regarding embodiments in conjunction with “Full solar cells having electrical contacts (that include busbars) coupled to their front and back surfaces” and FIG. 11 (i.e., regarding p and n type solar cells)—where, in this case, the cells are busbarless.

In accordance with one or more such embodiments, a portion of the free-standing metallic article that connects adjacent cells may be comprised, for example, of straight metallization that does not extend through cell-to-cell gaps, or straight metallization that does not extend into cell-to-cell gaps.

In accordance with one or more embodiments, the gaps between two adjacent solar cell edges can be in a range from about 5 mm to about 0.001 mm. In further addition, in accordance with one or more further embodiments, gaps between two adjacent cell edges can be reduced from 2 mm to less than 0.5 mm (for example, the gaps can be reduced to small dimensions such as, for example, 0.001 mm).

XII. Embodiments with Same or Different Electrical Contacts on Front and Back Surfaces

Although embodiments of solar modules described above comprise the same type of metallization on the front and back surfaces of solar cells (for example, busbars on front and back surfaces), further embodiments of solar modules exist where: (a) solar cells have different types of metallization (i.e., electrical contacts) coupled to their front and back surfaces; (b) different types of electrical connectors provide intercell connections in accordance with the above-described patterns; and (c) the solar module comprises solar cells that are connected in accordance with the above-described patterns. The term “above-described patterns” means that, in accordance with such embodiments, a solar module is comprised of one or more strings of solar cells having alternating negative and positive metallization (i.e., electrical contacts) coupled to the front surfaces of adjacent cells and, therefore, corresponding alternating positive and negative metallization (i.e., electrical contacts) coupled to the back surfaces of adjacent cells—where the solar cells are connected in series. In other words, in accordance with one or more such embodiments, the solar module comprises one or more strings of solar cells having alternating negative and positive front surfaces of adjacent cells and, therefore, corresponding alternating positive and negative back surfaces of adjacent cells—where the solar cells are connected in series.

As such, embodiments exist with full, half, or cut solar cells where the electrical contact coupled to the surface of one side includes busbars and the electrical contact coupled to the surface of the other side: (a) includes busbars (these embodiments were described above); (b) has wires coupled thereto for interconnection of cells; (c) comprises a mesh metallization structure with electrical connection pads; (d) has a free-standing metallic article coupled thereto for interconnection of cells; and (e) comprises a padless mesh metallization structure. In addition, embodiments exist with full, half, or cut solar cells where the electrical contact coupled to the surface of one side has wires coupled thereto for interconnection of cells and the electrical contact coupled to the surface of the other side: (a) has wires coupled thereto for interconnection of cells (these embodiments were described above); (b) comprises a mesh metallization structure with electrical connection pads; (c) has a free-standing metallic article coupled thereto for interconnection of cells; and (d) comprises a padless mesh metallization structure. In further addition, embodiments exist with full, half, or cut solar cells where the electrical contact coupled to the surface of one side comprises a mesh metallization structure with electrical connection pads and the electrical contact coupled to the surface of other side: (a) comprises a mesh metallization structure with electrical connection pads (these embodiments were described above); (b) has a free-standing metallic article coupled thereto for interconnection of cells; and (c) comprises a padless mesh metallization structure. In further addition, embodiments exist with full, half, or cut solar cells where the electrical contact coupled to the surface of one side has a free-standing metallic article coupled thereto for interconnection of cells and the electrical contact coupled to the surface of the other side: (a) has a free-standing article coupled thereto for interconnection of cells (these embodiments were described above) and (b) comprises a padless mesh metallization structure. In further addition, embodiments exist with full, half, or cut solar cells where the electrical contact coupled to the surface of one side comprises a padless mesh metallization structure and the electrical contact coupled to the surface of the other side comprises a padless mesh metallization structure. Thus, in the above, when one side and the other side have different metallizations, each of the above, therefore, in fact, refers to two embodiments each for solar modules comprised of full, half or cut cells, respectively.

In addition, further embodiments exist wherein a solar module is comprised of one or more strings of solar cells having alternating negative and positive front surface metallization (i.e., electrical contacts) coupled to the front surfaces of adjacent cells and, therefore, corresponding alternating positive and negative back surface metallization (i.e., electrical contacts) coupled to the back surfaces of adjacent cells—where the solar cells are connected in series (in other words, in accordance with one or more such embodiments, the solar module comprises one or more strings of solar cells having alternating negative and positive front surfaces of adjacent cells and, therefore, corresponding alternating positive and negative back surfaces of adjacent cells—where the solar cells are connected in series.) and where the bottom contacts of the solar cells are attached to metallized conductive backsheets or patterned conductive foils (for example, where a backsheet comprises a metal pattern). In accordance with one or more such embodiments, the bottom contacts of the solar cells can be electrically connected in the above-described patterns by soldering to the patterned conductive backsheet, while the front contacts of the solar cells are formed in accordance one of the above-described embodiments and the front contacts are electrically connected in accordance with the above-described patterns using, for example and without limitation, ribbons, wires and free standing metallic articles.

In light of the descriptions provided herein, it should be clear to one of ordinary skill in the art how to fabricate any one of the embodiments set forth above.

XIII. Mesh Metallization Structure with Electrical Connection Pads on Front Surfaces and Busbars on Back Surfaces

One or more embodiments exist where front surfaces of solar cells have electrical contacts comprised of a mesh metallization structure with electrical connection pads coupled thereto (fabricated as described above) and back surfaces of the solar cells have electrical contacts that include busbars coupled thereto (for example, anywhere from one (1) up to two-hundred (200) busbars—such a busbar arrangement can be fabricated, for example and without limitation, by screen printing using Ag paste). In accordance with one or more such embodiments, a solar module is formed which is comprised of one or more strings of solar cells having alternating negative and positive metallizations (i.e., electrical contacts) coupled to the front surfaces of adjacent cells and, therefore, corresponding alternating positive and negative metallizations (i.e., electrical contacts) coupled to the back surfaces of adjacent cells—where the solar cells are connected in series. In other words, in accordance with one or more such embodiments, a solar module comprises solar cells having alternating negative and positive front surfaces of adjacent cells and, therefore, corresponding alternating positive and negative back surfaces of adjacent cells—where the solar cells are connected in series. In accordance with such an embodiment, the solar cells could be fabricated using full solar cells, half solar cells or cut solar cells.

In accordance with one or more embodiments, a solar module can be fabricated, for example and without limitation, using the types of solar cells described above regarding embodiments in conjunction with “Full solar cells having electrical contacts (that include busbars) coupled to their front and back surfaces” and FIG. 11 (i.e., regarding p and n type solar cells)—where, in this case, the cells have the above-described metallizations affixed thereto.

In accordance with one or more such embodiments, the solar cells are connected by electrical connectors (i.e., the cell-to-cell, electrical connectors of electrical connection pads on the front surfaces like the connections of front surfaces shown in FIG. 23 and electrical connectors of busbars on the back surfaces like the connections of back surfaces shown in FIG. 11) may be, for example and without limitation, ribbons, such as straight ribbons that do not extend through cell-to-cell gaps, or straight ribbons that do not extend into cell-to-cell gaps. Examples of suitable such ribbons were described above regarding embodiments in conjunction with “Full solar cells having electrical contacts (that include busbars) coupled to their front and back surfaces” and FIG. 11. The ribbons may be affixed to the electrical conduction pads (disposed, for example, close to the cell's edge) and to the busbars (where, for example and without limitation, the electrical connectors extend completely over the busbars on adjacent cells) by soldering, by use of conductive bonding, or by use of other suitable electrical bonding methods. For example and without limitation, such solder conduction pads can be round (having, for example and without limitation, a 2 mm diameter) or they can be square (having, for example and without limitation, a 2 mm side dimension). In addition, the pads can be placed, for example and without limitation, as close as 1 mm or as close as 0.5 mm or as close as 0.1 mm away from a cell's edge. In addition, the electrical connectors may be any one of a number of conducting tapes that are well known, such as conductive adhesive tape. In further addition, the electrical connectors may be interconnectors 600 or 610 described above in conjunction with FIG. 40.

XIV. Free-Standing Metallic Article Interconnects Electrical Contacts on Front Surfaces and Busbars on Back Surfaces

One or more embodiments exist wherein a free-standing metallic article (fabricated as described above) is coupled to electrical contacts coupled to front surfaces of solar cells (such as the metallizations shown in FIGS. 37A and 37B) to electrically interconnect the cells and (b) back surfaces have electrical contacts (that include busbars, for example, anywhere from one (1) up to two-hundred (200) busbars). Such a busbar arrangement can be fabricated, for example and without limitation, by screen printing using Ag paste), the busbars being coupled to a mesh metallization structure (for example and without limitation, fingers) coupled to the back surfaces. In accordance with one or more such embodiments, a solar module is formed which is comprised of one or more strings of solar cells having alternating negative and positive metallizations (i.e., electrical contacts) coupled to the front surfaces of adjacent cells and, therefore, corresponding alternating positive and negative metallizations (i.e., electrical contacts) coupled to the back surfaces of adjacent cells—where the solar cells are connected in series. In other words, in accordance with one or more such embodiments, a solar module comprises one or more strings of solar cells having alternating negative and positive front surfaces of adjacent cells and, therefore, corresponding alternating positive and negative back surfaces of adjacent cells—where the solar cells are connected in series. In accordance with such an embodiment, the solar cells can be fabricated using full solar cells, half solar cells or cut solar cells.

In accordance with one or more embodiments, a solar module can be fabricated, for example and without limitation, using the types of solar cells described above regarding embodiments in conjunction with “Full solar cells having electrical contacts (that include busbars) coupled to their front and back surfaces” and FIG. 11 (i.e., regarding p and n type solar cells)—where, in this case, the cells have the above-described metallizations coupled thereto.

In accordance with one or more such embodiments, the front surfaces of solar cells are connected by electrical connectors, i.e., cell-to-cell connections formed using free-standing metallic articles like the connections of front surfaces described above regarding embodiments using free-standing metallic articles on cell-to-cell interconnection on the front and back surfaces and electrical connectors of busbars on the back surfaces like the connections of back surfaces shown in FIG. 11.

XV. Embodiments with Combinations of Full, Half and Cut Cells

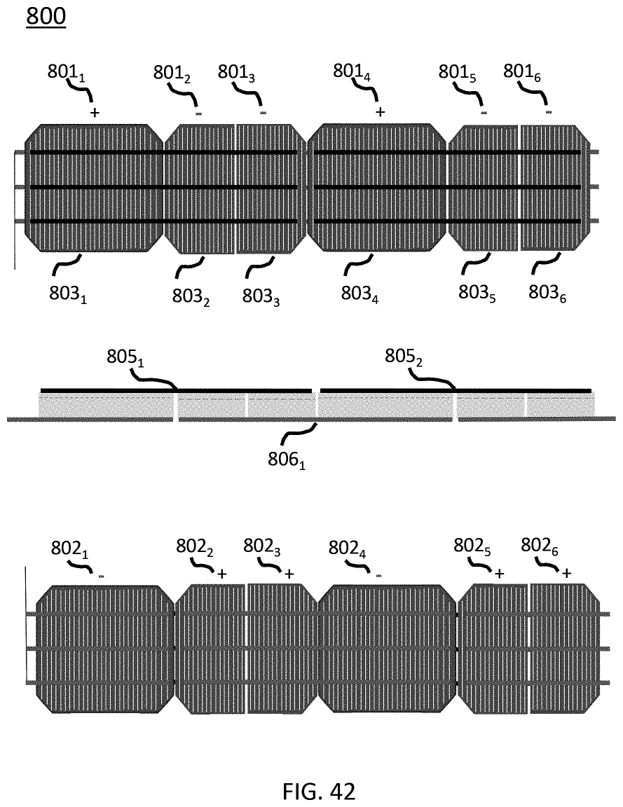

FIG. 42 shows: (a) a top view of a portion of the top side of solar module 800 that is fabricated in accordance with one or more embodiments; (b) a cross-section of the portion of solar module 800 (where the electrical contacts are not shown in the cross-section to facilitate understanding); and (c) a bottom view of the portion of the back side of solar module 800, respectively.

As one can readily appreciate from FIG. 42, solar module 800 is the same as solar module 220 shown in FIG. 10 and FIG. 11 (see section I.), except that, instead of being comprised of full solar cells, module 800 is comprised of one or more strings of adjacent groups of a full solar cell next to a half solar cell which, itself, is next to another half solar cell where: (a) the front surface of the full solar cell in the group has metallization (i.e., an electrical contact) of a first polarity and the front surface of each half cell in the group has metallization (i.e., an electrical contact) of the opposite polarity (for example, +−− or −++) and (b) the back surface of the full solar cell in the group has metallization (i.e., an electrical contact) of the opposite polarity and the back surface of each half cell in the group has metallization (i.e., an electrical contact) of the first polarity (for example, −++ or +−−). In other words, in accordance with one or more such embodiments, solar module 800 comprises one or more strings of adjacent groups of a full solar cell next to a half solar cell which, itself, is next to another half solar cell where: (a) the front surface of the full solar cell in the group has a first polarity and the front surface of each half cell in the group has the opposite polarity (for example, +−− or −++) and (b) the back surface of the full solar cell in the group has the opposite polarity and the back surface of each half cell in the group has the first polarity (for example, −++ or +−−). In accordance with one or more such embodiments, plus signs 801₁ and 801₄ and minus signs 801₂, 801₃, 801₅ and 801₆ show the electrical polarity of metallization (i.e., electrical contacts) coupled to the front surfaces of full solar cells 803₁ and 803₄ and half solar cells 803₂, 803₃, 803₅ and 803₆ (i.e., a negative metallization (a negative front electrical contact) collects negative charge carriers from a negative front surface, which negative front surface provides negative charge carriers when the particular solar cell is in operation and a positive metallization (a positive front electrical contact) collects positive charge carriers from a positive front surface, which positive front surface provides positive charge carriers when the particular solar cell is in operation) In addition, in accordance with one or more such embodiments, minus signs 802₁ and 802₄ and plus signs 802₂, 802₃, 802₅ and 802₆ show the electrical polarity of metallization (i.e., electrical contacts) coupled to the back surfaces of full solar cells 803₁ and 803₄ and half solar cells 803₂, 803₃, 803₅ and 803₆ (i.e., a negative metallization (a negative back electrical contact) collects negative charge carriers from a negative back surface, which negative back surface provides negative charge carriers when the particular solar cell is in operation and a positive metallization (a positive back electrical contact) collects positive charge carriers from a positive back surface, which positive back surface provides positive charge carriers when the particular solar cell is in operation). To illustrate the principle in this case, in accordance with one or more embodiments, the electrical contacts coupled to the front and back surfaces of the solar cells include busbars. In addition, in accordance with one or more such embodiments: (a) front electrical connectors 805₁ provide electrical connection between metallization (i.e., electrical contacts) coupled to the front surfaces of full solar cell 803₁, half solar cell 803₂ and half solar cell 803₃ (in FIG. 42, front electrical connectors 805₁ (for example, ribbons, that cover and couple to the busbars) couple to the front contacts of full solar cell 803₁, half solar cell 803₂ and half solar cell 803₃); (b) front electrical connectors 805₂ provide electrical connection between metallization (i.e., electrical contacts) coupled to the front surfaces of full solar cell 803₄, half solar cells 803₅ and half solar cell 803₆ (in FIG. 42, front electrical connectors 805₂ (for example, ribbons, that cover and couple to the busbars) couple to the front contacts of full solar cell 803₄, half solar cell 803₅ and half solar cell 803₆); and (c) back electrical connectors 806₁ provide electrical connection between metallization (i.e., electrical contacts) coupled to the back surface of half solar cell 803₂, half solar cell 803₃ and full solar cell 803₄ (in FIG. 42, back electrical connectors 806₁ (for example, ribbons, that cover and couple to the busbars) couple to the back contacts of half solar cell 803₂, half solar cell 803₃ and full solar cell 803₄). In accordance with one or more such embodiments, the front and back electrical connectors (i.e., the cell-to-cell, electrical connectors of metallizations (i.e., electrical contacts) which are connected in the above-described configuration) (where, for example and without limitation, the electrical connectors extend completely over the busbars on the surfaces of the cells in a group) may be, for example and without limitation, ribbons, such as straight ribbons that do not extend through cell-to-cell gaps, or straight ribbons that do not extend into cell-to-cell gaps. Examples of suitable such ribbons were described above regarding embodiments in conjunction with “Full solar cells having electrical contacts (that include busbars) coupled to front and back surfaces” and FIG. 11 (see section I.). The ribbons may be affixed to busbars by soldering, by use of conductive bonding, or by use of other known electrical bonding methods. In addition, the electrical connectors may be any one of a number of conducting tapes that are well known, such as conductive adhesive tape. In further addition, the electrical connectors may be interconnectors 600 or 610 described above in conjunction with FIG. 40. In further addition, the busbars and the electrical connections set forth above may be comprised of ribbons where the busbars and electrical connections are fabricated at the same time.

In accordance with one or more embodiments, gaps between two adjacent solar cell edges (i.e., gaps shown in FIG. 42) can be in a range from about 5 mm to about 0.001 mm. In further addition, in accordance with one or more further embodiments, gaps between two adjacent cell edges can be reduced from 2 mm to less than 0.5 mm (for example, the gaps can be reduced to small dimensions such as, for example, 0.001 mm).

In accordance with one or more embodiments, solar modules like solar module 800 can be fabricated, for example and without limitation, using the types of full solar cells and half solar cells described above regarding embodiments in conjunction with “Full solar cells having electrical contacts (that include busbars) coupled to front and back surfaces” and FIG. 11 (see section I.) (i.e., regarding p and n type solar cells).

In light of the above, it should be understood by those of ordinary skill in the art that further embodiments exist where, instead of two half solar cells in a group), (a) there are a number of cut solar cells in a group having the same surface electrical polarity pattern as set forth above and (b) the number and size of the cut solar cells is sufficient to provide substantially the same amount of current as that produced by the full solar cell of the group. In addition, although embodiments were described wherein electrical contacts coupled to the front and back surfaces of the solar cells include busbars, as set forth above in section XII., further embodiments of such solar modules exist where: (a) the types of solar cells are different (for example and without limitation, using the types of solar cells described above regarding embodiments in conjunction with “Full solar cells having electrical contacts (that include busbars) coupled to front and back surfaces” and FIG. 11 (i.e., regarding p and n type solar cells)—where, in the particular case, the solar cells have the appropriate metallization); (b) solar cells have different types of metallization (i.e., electrical contacts) coupled to their front and back surfaces; (c) different types of electrical connectors provide intercell connections in accordance with the patterns described in this section; and (d) the solar module comprises groups of solar cells that are connected in accordance with the above-described patterns. In addition, in light of the descriptions set forth herein, it should be clear to those of ordinary skill in the art how to fabricate each of these further embodiments.

XVI. Embodiments with Alternating Groups of Negative and Positive Electrical Contact Solar Cells

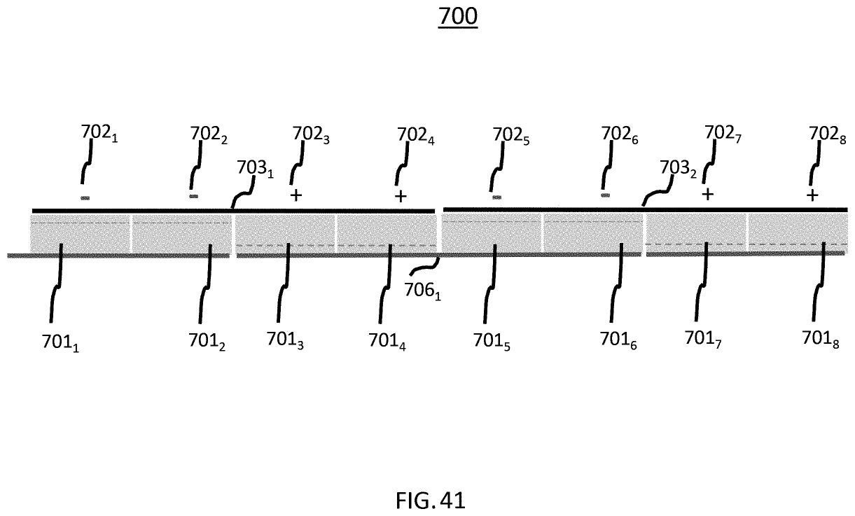

FIG. 41 shows a cross-section of a portion of solar module 700 that is fabricated in accordance with one or more embodiments (where the electrical contacts are not shown in the cross-section to facilitate understanding). As shown in FIG. 41, the portion of solar module 700 comprises full solar cells 701₁-701₈ having metallization that includes busbars (i.e., electrical contacts) coupled to their front and back surfaces. As shown in FIG. 41: (a) minus sign 702₁ indicates that solar cell 701₁ has a negative metallization (i.e., electrical contact) coupled to its front surface; (b) minus sign 702₂ indicates that solar cell 701₂ has a negative metallization (i.e., electrical contact) coupled to its front surface; (c) plus sign 702₃ indicates that solar cell 701₃ (adjacent to solar cell 701₂) has a positive metallization (i.e., electrical contact) coupled to its front surface; (d) plus sign 702₄ indicates that solar cell 701₄ (adjacent to solar cell 701₃) has a positive metallization (i.e., electrical contact) coupled to its front surface; (e) minus sign 702₅ indicates that solar cell 701₅ (adjacent to solar cell 701₄) has a negative metallization (i.e., electrical contact) coupled to its front surface; (f) minus sign 702₆ indicates that solar cell 701₆ (adjacent to solar cell 701₅) has a negative metallization (i.e., electrical contact) coupled to its front surface; and (g) so forth. Thus, in accordance with one or more such embodiments, solar module 700 comprises one or more strings of pairs of solar cells (where each solar cell in a pair has the same polarity of metallization (i.e., electrical contact) coupled to its front surface) and where adjacent pairs have different polarity of metallization (i.e., electrical contact) coupled to their front surfaces. As a result, the solar module has alternating negative and positive metallization (i.e., electrical contacts) of pairs coupled to the front surfaces of adjacent pairs and, therefore, corresponding alternating positive and negative metallization (i.e., electrical contacts) of pairs coupled to the back surfaces of adjacent pairs—where the pairs are connected in series. In other words, in accordance with one or more such embodiments, solar module 800 comprises one or more strings of adjacent groups comprised of two (2) full solar cells adjacent to each other and adjacent to two (2) further full cells which are adjacent to each other where: (a) the front surface of each of the first two full solar cells of the group has a first polarity and the front surface of each of the second two full solar cells of the group has the opposite polarity (for example, ++−− or −−++) and (b) the back surface of each of the first two full solar cells of the group has the opposite polarity and the back surface of each of the second two full solar cells of the group has the first polarity (for example, −−++ or ++−−).

As further shown in FIG. 41, in accordance with one or more embodiments: (a) front electrical connectors 703₁ provide electrical connection between metallization (i.e., electrical contacts) coupled to the front surface of full solar cells 701₁-701₄ (in FIG. 41, front electrical connectors 703₁ (for example, ribbons, that cover and couple to the busbars) couple to the front contacts of full solar cells 701₁-701₄); (b) front electrical connectors 703₂ provide electrical connection between metallization (i.e., electrical contacts) coupled to the front surface of full solar cells 701₅-701₆ (in FIG. 41, front electrical connectors 703₂ (for example, ribbons, that cover and couple to the busbars) couple to the front contacts of full solar cells 701₅-701₆); and (c) back electrical connectors 706₁ provide electrical connection between metallization (i.e., electrical contacts) coupled to the back surface of full solar cells 701₃-701₆ (in FIG. 41, back electrical connectors 706₁ (for example, ribbons, that cover and couple to the busbars) couple to the back contacts of full solar cells 701₃-701₆).

In accordance with one or more such embodiments, the front and back electrical connectors (i.e., the cell-to-cell, electrical connectors of metallizations (i.e., electrical contacts) which are connected in the above-described configuration) (where, for example and without limitation, the electrical connectors extend completely over the busbars on the surfaces of the cells in a group) may be, for example and without limitation, ribbons, such as straight ribbons that do not extend through cell-to-cell gaps, or straight ribbons that do not extend into cell-to-cell gaps. Examples of suitable such ribbons were described above regarding embodiments in conjunction with “Full solar cells having electrical contacts (that include busbars) coupled to front and back surfaces” and FIG. 11 (see section I.). The ribbons may be affixed to busbars by soldering, by use of conductive bonding, or by use of other known electrical bonding methods. In addition, the electrical connectors may be any one of a number of conducting tapes that are well known, such as conductive adhesive tape. In further addition, the electrical connectors may be interconnectors 600 or 610 described above in conjunction with FIG. 40. In further addition, the busbars and the electrical connections set forth above may be comprised of ribbons where the busbars and electrical connections are fabricated at the same time.

Although the above-described embodiments related to solar cells where electrical contacts coupled to the front and back surfaces of the solar cells include busbars, in light of section XII., it should be clear to those of ordinary skill in the art that further embodiments, like solar module 700, exist where: (a) the types of solar cells are different (for example and without limitation, using the types of solar cells described above regarding embodiments in conjunction with “Full solar cells having electrical contacts (that include busbars) coupled to front and back surfaces” and FIG. 11 (i.e., regarding p and n type solar cells)—where, in the particular case, the solar cells have the appropriate metallization); (b) solar cells have different types of metallization (i.e., electrical contacts) coupled to their front and back surfaces; (c) different types of electrical connectors provide intercell connections in accordance with the patterns described in this section; (d) the solar cells may be full, half or cut cells and (e) the solar module comprises groups of solar cells that are connected in accordance with the above-described patterns. In addition, in light of the descriptions set forth herein, it should be clear to those of ordinary skill in the art how to fabricate each of these further embodiments.

It should also be understood that, although solar module 700 was described as having one or more strings of groups of adjacent pairs of solar cells where the adjacent pairs have alternating negative and positive front surfaces, further embodiments exist where groups of solar cells are utilized in the same manner, i.e., as having one or more strings of groups of adjacent sets of solar cells where the adjacent sets have alternating negative and positive front surfaces and, therefore, corresponding alternating positive and negative back surfaces—where the groups are connected in series.

XVII. Embodiments with Solar Cells Having Front Surfaces with the Same Charge Polarity with Same or Different Electrical Contacts on Front and Back Surfaces

One or more embodiments of a solar module comprise solar cells whose front surfaces all have the same charge polarity (i.e., the solar cell front surfaces are adapted to provide charge carriers of the same charge polarity when the solar cells are in operation). Such further embodiments of solar modules exist where: (a) solar cells have the same or different types of metallization (i.e., electrical contacts) coupled to their front and back surfaces; (b) the same or different types of electrical connectors provide intercell connections in accordance with the following-described patterns; and (c) the solar module comprises solar cells that are connected in accordance with the following-described patterns. The term “following-described patterns” means that, in accordance with such embodiments, a solar module is formed which is comprised of solar cells (for example and without limitation, those set forth below) having the same polarity metallization (as electrical contacts) coupled to the front surfaces and the same polarity metallization (as electrical contacts) coupled to the back surfaces of adjacent cells—where the solar cells are connected in series.

As such, embodiments exist with full, half, or cut cells where the electrical contact coupled to the surface of one side includes busbars and the electrical contact coupled to the surface of the other side: (a) has wires coupled thereto for interconnection of cells; (b) comprises a mesh metallization structure with pads; (c) has a free-standing metallic article coupled thereto for interconnection of cells; and (d) comprises a padless mesh metallization structure. In addition, embodiments exist with full, half, or cut solar cells where the electrical contact coupled to the surface of one side has wires coupled thereto for interconnection of cells and the electrical contact coupled to the surface of the other side: (a) has wires coupled thereto for interconnection of cells; (b) comprises a mesh metallization structure with pads; (c) has a free-standing metallic article coupled thereto for interconnection of cells; and (d) comprises a padless mesh metallization structure. In further addition, embodiments exist with full, half, or cut solar cells where the electrical contact coupled to the surface of one side comprises a mesh metallization structure with pads and the electrical contact coupled to the surface of the other side: (a) comprises a mesh metallization coupled with pads; (b) has a free-standing metallic article coupled thereto for interconnection of cells; and (c) comprises a padless mesh metallization structure. In further addition, embodiments exist with full, half, or cut solar cells where the electrical contact coupled to the surface of one side has a free-standing metallic article coupled thereto for interconnection of cells and the electrical contact coupled to the surface of the other side: (a) has a free-standing metallic article coupled thereto for interconnection of cells and (b) comprises a padless mesh metallization structure. In further addition, embodiments exist with full, half, or cut solar cells where the electrical contact coupled to the surface of one side comprises a padless mesh metallization structure coupled and the electrical contact coupled to the surface of the other side comprises a padless mesh metallization structure. Thus, in the above, when one side and the other side have different electrical contacts, each of the above, therefore, in fact, refers to two embodiments each for solar modules comprised of full, half or cut cells, respectively.

In light of the descriptions provided herein, it should be clear to one of ordinary skill in the art how to fabricate any one of the embodiments set forth above.

XVIII. Embodiment: Same Charge Polarity and Mesh Metallization Structure with Electrical Connection Pads on Front and Back Surfaces

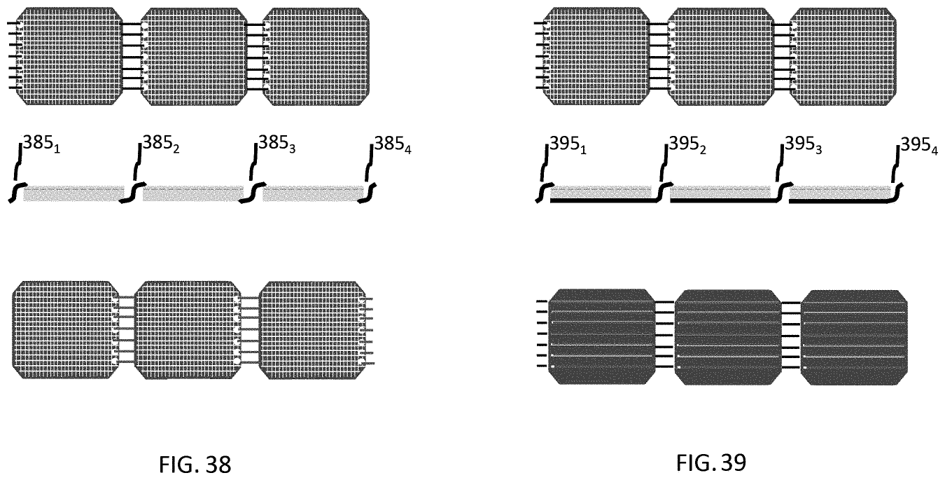

One or more embodiments of a solar module comprise solar cells whose front surfaces all have the same charge polarity. In accordance with one or such embodiments, electrical contacts coupled to the front and back surfaces of the solar cells are comprised of a mesh metallization structure with electrical connection pads (for example, refer to FIGS. 34 and 35 discussed above). FIG. 38 shows: (a) a top view of a portion of the top side of a solar module that is fabricated in accordance with one or more embodiments; (b) a cross-section of the portion of the solar module (where the electrical contacts are not shown in the cross-section to facilitate understanding); and (c) a bottom view of the portion of the back side of the solar module, respectively—where the solar cells are connected in series. As shown in FIG. 38, adjacent cells are connected, for example and without limitation, by: (a) soldering or conductively bonding (as described above) electrical connectors 385₁-385₄ to electrical connection pads on the back surface of a cell; (b) extending electrical connectors 385₁-385₄ through gaps between adjacent cells to the front surface of the adjacent cell; and (c) soldering or conductively bonding electrical connectors 385₁-385₄ to electrical connection pads on the front surface of the adjacent cell. In accordance with such an embodiment, solar modules can be fabricated using full solar cells, half solar cells or cut solar cells.

In accordance with one or more embodiments, a solar module can be fabricated, for example and without limitation, using the types of solar cells described above regarding embodiments in conjunction with “Full solar cells having electrical contacts (that include busbars) coupled to front and back surfaces” and FIG. 11 (i.e., regarding p and n type solar cells)—where, in this case, the cells have the appropriate electrical contacts (i.e., a mesh metallization structure with pads on the front surface and the back surface).

In accordance with one or more embodiments, the electrical connectors may be ribbons such as those described above in conjunction with FIG. 11. In addition, the electrical connectors may be any one of a number of conducting tapes that are well known, such as conductive adhesive tape.

XIX. Embodiment: Same Charge Polarity and Mesh Metallization Structure with Electrical Connection Pads on Front Surfaces and Busbars on Back Surfaces

One or more embodiments of a solar module comprise solar cells whose front surfaces all have the same charge polarity (i.e., the solar cell front surfaces are adapted to provide charge carriers of the same charge polarity when the solar cells are in operation). In accordance with one or such embodiments, electrical contacts coupled to the front surfaces of the solar cells are comprised of a mesh metallization structure with electrical connection pads (for example, refer to FIGS. 34 and 35 discussed above) and electrical contacts coupled to the back surfaces of the solar cells include busbars. FIG. 39 shows: (a) a top view of a portion of the top side of a solar module that is fabricated in accordance with one or more embodiments; (b) a cross-section of the portion of the solar module (where the electrical contacts are not shown in the cross-section to facilitate understanding); and (c) a bottom view of the portion of the back side of the solar module, respectively—where the solar cells are connected in series. As shown in FIG. 39, adjacent cells are connected, for example and without limitation, by: (a) soldering or conductively bonding (as described above) electrical connectors 395₁-395₄ to busbars on the back surface of a cell; (b) extending electrical connectors 395₁-395₄ through gaps between adjacent cells to the front surface of the adjacent cell; and (c) soldering or conductively bonding electrical connectors 395₁-395₄ to electrical connection pads on the front surface of the adjacent cell. In accordance with such an embodiment, solar modules can be fabricated using full solar cells, half solar cells or cut solar cells.

In accordance with one or more embodiments, a solar module can be fabricated, for example and without limitation, using the types of solar cells described above regarding embodiments in conjunction with “Full solar cells having electrical contacts (that include busbars) coupled to front and back surfaces” and FIG. 11 (i.e., regarding p and n type solar cells)—where, in this case, the cells have the appropriate electrical contacts (i.e., mesh metallization with pads on the front surface and contacts that have busbars on the back surface).

In accordance with one or more embodiments, a solar module can be fabricated, for example and without limitation, using the types of solar cells described above regarding embodiments in conjunction with “Full solar cells having electrical contacts (that include busbars) coupled to front and back surfaces” and FIG. 11 (i.e., regarding p and n type solar cells)—where, in this case, the cells have the appropriate electrical contacts (i.e., mesh metallization structure with pads on the front surface and contacts that have busbars on the back surface).

In accordance with one or more embodiments, the electrical connectors may be ribbons such as those described above in conjunction with FIG. 11 (where, for example and without limitation, the ribbons extend completely over the busbars on the back surface of the cells). In addition, the electrical connectors may be any one of a number of conducting tapes that are well known, such as conductive adhesive tape.

In light of the above, it should be clear to those of ordinary skill in the art that further embodiments exist that, like embodiments described above, are comprised of electrical connections: (a) from a back surface of a first cell; (b) to a front surface of an adjacent cell; and (c) that extend through gaps between the adjacent cells. In fact, it should be clear that such further embodiments exist where: (a) metallization (i.e., electrical contacts) coupled to the front and back surfaces of cells are the same type of metallization; and (b) metallization (i.e., electrical contacts) coupled to the front and back surfaces of cells are different. Further, in light of the description provided herein, it should be clear to those of ordinary skill in the art how to fabricate each of these further embodiments. As an example, embodiments where metallization (i.e., electrical contacts) coupled to front and back surfaces comprise a padless mesh metallization structure are fabricated using a wire mesh (like wire mesh 950 described in section IX. above) for intercell connection. However, in this case, the wire mesh is connected to a padless mesh metallization structure coupled to the back surface of one cell (in the manner described above in section X.), is extended through a gap between adjacent cells to the front surface of the adjacent cell, and is connected to a padless mesh metallization structure coupled to the front surface of the adjacent cell.

All the above-described solar cells used in providing one or more embodiments, can all be metalized using, for example and without limitation, Ag paste, screen printable Cu paste, inkjet printable Cu materials and Cu plating.

Embodiments of the present invention described above are exemplary, and many changes and modifications may be made to the description set forth above by those of ordinary skill in the art while remaining within the scope of the invention. For example, although various embodiments described electrical connections between cells comprising straight ribbons or straight wires, further embodiments may use other than straight ribbons or straight wires. As such, the scope of the invention should be determined with reference to the appended claims along with their full scope of equivalents.

What is claimed is:

1. A solar module that comprises:
a first pair of adjacent first and second solar cells;
a second pair of adjacent first and second solar cells; wherein:
the first pair is adjacent to the second pair;
the first solar cell of each pair has a first polarity front surface and the second solar cell of each pair has an opposite polarity front surface; and
the first solar cell of the second pair is adjacent to the second solar cell of the first pair.

2. The solar module of claim 1 wherein:
the first solar cell and the second solar cell of the first and second pairs each has a front electrical contact coupled to its front surface; and
a front electrical connector of each pair connects the front electrical contacts of the first and second solar cells of each pair.

3. The solar module of claim 2 wherein:
the first solar cell and the second solar cell of the first and second pairs each has a back electrical contact coupled to its back surface; and
a back electrical connector connects the back electrical contact of the second solar cell of the first pair to the back electrical contact of the first solar cell of the second pair.

4. The solar module of claim 2 wherein gaps between the solar cells are equal to or less than 2 mm.

5. The solar module of claim 3 wherein gaps between the solar cells are equal to or less than 2 mm.

6. The solar module of claim 2 wherein the first and second solar cell of each pair is a full solar cell, a half solar cell or a cut solar cell.

7. The solar module of claim 3 wherein the first and second solar cell of each pair is a full solar cell, a half solar cell or a cut solar cell.

8. The solar module of claim 4 wherein the first and second solar cell of each pair is a full solar cell, a half solar cell or a cut solar cell.

9. The solar module of claim 2 wherein the front electrical contact of the first and second solar cells of each pair each comprises one or more busbars; and
the front electrical connectors of the first and second solar cell of each pair comprises one or more ribbons coupled to the one or more busbars of the front electrical contacts of the first and second solar cell of each pair.

10. The solar module of claim 2 wherein the front electrical contact of the first and second solar cell of each pair each comprises one or more busbars; and
the front electrical connectors of the first and second solar cell of each pair comprises one or more ribbons coupled to the one or more busbars of the front electrical contacts of the first and second solar cell of each pair, which ribbons are soldered to the busbars.

11. The solar module of claim 2 wherein the front electrical connector of the first and second solar cell of each pair comprises wires coupled to the front electrical contacts of the first and second solar cell of each pair.

12. The solar module of claim 2 wherein the front electrical connectors of the first and second solar cell of each pair comprises a free-standing metallic article coupled to the front electric contacts of the first and second solar cell of each pair.

13. The solar module of claim 2 wherein the front electrical contact of the first and second solar cells of each pair each comprises a mesh metallization structure with one or more electrical connection pads; and
the front electrical connectors of the first and second solar cell of each pair comprises one or more ribbons coupled to the one or more electrical connection pads of the front electrical contacts of the first and second solar cell of each pair.

14. The solar module of claim 2 wherein the front electrical contact of the first and second solar cells of each pair each comprises a padless mesh metallization structure; and
the front electrical connectors of the first and second solar cell of each pair comprises a wire mesh coupled to the front electrical contacts of the first and second solar cell of each pair.

15. The solar module of claim 9 wherein the first polarity front surface is negative and the opposite polarity is positive.

16. The solar module of claim 15 wherein the solar cells with negative front surfaces are p type front junction cells or n type back junction cells.

17. The solar module of claim 15 wherein the solar cells with positive front surfaces are n type front junction cells or p type back junction cells.

18. A solar module that comprises:
one or more strings of solar cells wherein at least one of the one or more strings comprises:
a first pair of adjacent first and second solar cells;
a second pair of adjacent first and second solar cells; wherein:
the first pair is adjacent to the second pair;
the first solar cell of each pair has a first polarity front surface and the second solar cell of each pair has an opposite polarity front surface; and
the first solar cell of the second pair is adjacent to the second solar cell of the first pair.

19. The solar module of claim 18 wherein:
the first solar cell and the second solar cell of the first and second pairs each has a front electrical contact coupled to its front surface; and
a front electrical connector of each pair connects the front electrical contacts of the first and second solar cells of each pair.

20. The solar module of claim 19 wherein:
the first solar cell and the second solar cell of the first and second pairs each has a back electrical contact coupled to its back surface; and
a back electrical connector connects the back electrical contact of the second solar cell of the first pair to the back electrical contact of the first solar cell of the second pair.
